(19) United States
(12) Patent Application Publication
(10) Pub. No.: US 2006/0160373 A1
(43) Pub. Date: Jul. 20, 2006

(54) Processes for planarizing substrates and encapsulating printable electronic features

(75) Inventors: Mark H. Kowalski, Albuquerque, NM (US); Karel Vanheusden, Placitas, NM (US); Chuck Edwards, Rio Rancho, NM (US)

Correspondence Address: Jaimes Sher, Esq.;Cabot Corporation, 5401 Venice Avenue NE, Albuquerque, NM, 87113, US

(73) Assignee: Cabot Corporation, Boston, MA (US)

(21) Appl. No.: 11/331,239

(22) Filed: Jan. 13, 2006

Related U.S. Application Data
(60) Provisional application No. 60/643,577, filed on Jan. 14, 2005.
(60) Provisional application No. 60/643,629, filed on Jan. 14, 2005.
(60) Provisional application No. 60/643,578, filed on Jan. 14, 2005.
(60) Provisional application No. 60/695,412, filed on Jul. 1, 2005.

(51) Int. Cl. H01L 21/31; H01L 21/469

(52) U.S. Cl. 438/778

(57) ABSTRACT

Processes for planarizing a substrate, for encapsulating a printed electronic feature and for forming a ramp feature. In various embodiments, the processes include the steps of: (a) applying a planarizing agent, an encapsulating agent or a ramping feature to a substrate or to an electronic feature disposed thereon, preferably through a direct write printing process, e.g., ink-jet printing, and (b) treating the applied agent under conditions effective to form a planarizing feature, an encapsulation layer or a ramping feature.

### CROSS REFERENCE TO RELATED APPLICATIONS

This patent application claims priority to U.S. Provisional Patent Application Ser. Nos. 60/643,577; 60/643,629; and 60/643,378, all filed on Jan. 14, 2005, and to U.S. Provisional Patent Application Ser. No. 60/695,412, filed on Jul. 1, 2005, the entireties of which are all incorporated herein by reference.

### FIELD OF THE INVENTION

The present invention relates to printing electronic features. More specifically, the invention relates to planarization and encapsulation techniques that may be used during the formation of printable electronic features.

### BACKGROUND OF THE INVENTION

The electronics, display and energy industries rely on the formation of coatings and patterns of conductive materials on substrates to form circuits on organic and inorganic substrates. The primary methods for generating these patterns are screen printing for features larger than about 100 μm and thin film and etching methods for features smaller than about 100 μm. Other subtractive methods to attain fine feature sizes include the use of photo-patternable pastes and laser trimming.

One consideration with respect to patterning of conductors is cost. Non-vacuum, additive methods generally entail lower costs than vacuum and subtractive approaches. Some of these printing approaches utilize high viscosity flowable liquids. Screen-printing, for example, uses flowable mediums with viscosities of thousands of centipoise. At the other extreme, low viscosity compositions can be deposited by methods such as ink-jet printing. However, low viscosity compositions are not as well developed as the high viscosity compositions.

One problem associated with the formation of printable electronic features is substrate variability. Although most substrates typically provide, at a macroscopic level, a substantially planar surface for receiving a printable electronic feature, such substrates often exhibit highly irregular surfaces on a microscopic level. These surface irregularities may result in variability of the electronic properties of the printable electronic features ultimately formed thereon. Accordingly, it may be difficult to repeatably form a printable electronic feature having desired electronic properties on an irregular substrate surface.

Thus, the need exists for processes for mitigating surface irregularities on a substrate surface and for providing the ability to repeatably manufacture printable electronic features having desired electronic properties regardless of such surface irregularities.

Another problem associated with electronic features formed by direct write (e.g., ink-jet) printing techniques is that they may exhibit circuit instability and variation due to atmospheric exposure. Conventionally, printable electronic features have been exposed to atmospheric air and moisture, e.g., as water vapor. Over time, the oxygen from air may oxidize the metallic components contained in the electronic feature causing a change in electrical properties. Similarly, water in the air may slowly react with the components in the electronic features, particularly resistive compositions contained in certain electronic features, to cause an undesired change in electrical properties.

Thus, the need also exists for more stable printable electronic features that are less susceptible to electronic variability caused by atmospheric exposure. The need also exists for processes for making such printable electronic features.

### SUMMARY OF THE INVENTION

The present invention is directed processes for planarizing substrate, encapsulating electronic features and forming ramping features on substrates. In one embodiment, for example, the invention is to a process for forming an electronic feature on a second substrate, the process comprising the steps of: (a) providing a first substrate having a first surface, wherein the first surface has a surface irregularity; (b) applying a planarizing agent to at least a portion of the first surface; (c) treating the applied planarizing agent under conditions effective to form the second substrate, the second substrate comprising the first substrate and a planarizing feature formed from the planarizing agent, wherein the second substrate has a planar surface formed at least in part of the planarizing feature, the planar surface being more planar (e.g., on a microscopic scale) than the first surface; and (d) forming an electronic feature on the planar surface.

Optionally, the first substrate comprises a base substrate and a preformed electronic feature disposed thereon, and the preformed electronic feature forms at least a portion of the surface irregularity. In this embodiment, the planarizing agent may be applied adjacent to the preformed electronic feature in step (b). The planar surface optionally is formed of at least the planarizing feature and a surface of the preformed electronic feature.

In another aspect, the surface irregularity comprises microscopic peaks and valleys. In this embodiment, the planarizing agent preferably fills at least a portion of the valleys in step (b).

The planarizing agent optionally comprises a UV curable composition. In this embodiment, step (c) comprises applying UV radiation to the applied planarizing agent. Additionally or alternatively, the planarizing agent comprises a polymer resin, and step (c) comprises applying a hardener to the planarizing agent under conditions effective to form the planarizing feature. Additionally or alternatively, the planarizing agent may comprise a liquid vehicle, and step (c) comprises heating the applied planarizing agent under conditions effective to remove a weight majority of the liquid vehicle from the applied planarizing agent. In this embodiment, the applied planarizing agent optionally is heated to a maximum temperature of not greater than about 200° C., not greater than about 150° C. or not greater than about 100° C. In this aspect, the planarizing agent optionally further comprises a polymer selected from the group consisting of an acrylic polymer, a polystyrene and a polyurethane. Additionally or alternatively, the planarizing agent preferably comprises a substantially non-conductive material selected from the group consisting of a dielectric material, a dielectric precursor, glass, silica, titania, alumina, and a silane. The planarizing agent preferably has a viscosity of less than about 50 centipoise. The planarizing agent may have a surface tension of from about 10 dynes/cm to about 50 dynes/cm. Optionally, the planarizing agent is direct write printed onto the at least a portion of the first surface in step (b). The planarizing feature may be hydrophobic or hydrophilic, and the planarizing agent optionally comprises an adhesion agent.

In one embodiment, the process further comprises the steps of applying a first ink onto at least a portion of the planarizing feature; and treating the first ink under conditions effective to form at least a portion of the electronic feature.

In another embodiment, the invention is to a process for forming an encapsulated electronic feature, the process comprising the steps of: (a) direct write printing a first ink onto a substrate; (b) treating the first ink under conditions effective to form at least a portion of a first electronic feature; (c) applying an encapsulating agent to the at least a portion of the first electronic feature; and (d) treating the applied encapsulating agent under conditions effective to form an encapsulated electronic feature comprising an encapsulation layer and the at least a portion of the first electronic feature.

The encapsulating agent optionally comprises a UV curable composition, and step (d) comprises applying UV radiation to the applied encapsulating agent. Additionally or alternatively, the encapsulating agent comprises a polymer resin, and step (d) comprises applying a hardener to the encapsulating agent under conditions effective to form the encapsulation layer. Additionally or alternatively, the encapsulating agent comprises a liquid vehicle, and step (d) comprises heating the applied encapsulating agent under conditions effective to remove a weight majority of the liquid vehicle from the applied encapsulating agent. In this aspect, the applied encapsulating agent is heated to a maximum temperature of not greater than about 200° C., not greater than about 1 50° C. or not greater than about 100° C. In this aspect, the encapsulating agent optionally further comprises a polymer selected from the group consisting of an acrylic polymer, a polystyrene and a polyurethane.

In this embodiment, the first ink optionally comprises a metallic composition, which optionally is selected from the group consisting of silver, gold, copper, nickel, cobalt, palladium, platinum, indium, tin, zinc, titanium, chromium, tantalum, tungsten, iron, rhodium, iridium, ruthenium, osmium and lead. In another aspect, the metallic composition comprises an alloy comprising at least two metals, each of the two metals being selected from the group consisting of silver, gold, copper, nickel, cobalt, palladium, platinum, indium, tin, zinc, titanium, chromium, tantalum, tungsten, iron, rhodium, iridium, ruthenium, osmium and lead. Additionally or alternatively, the first ink comprises a metal precursor to a metal, the metal being selected from the group consisting of silver, gold, copper, nickel, cobalt, palladium, platinum, indium, tin, zinc, titanium, chromium, tantalum, tungsten, iron, rhodium, iridium, ruthenium, osmium and lead.

The encapsulating agent optionally comprises a substantially non-conductive material selected from the group consisting of a dielectric material, a dielectric precursor, glass, silica, titania, alumina, and a silane. The encapsulating agent may have a viscosity of less than about 50 centipoise, and optionally has a surface tension of from about 10 dynes/cm to about 50 dynes/cm. Accordingly, the encapsulating agent may be direct write printed onto the at least a portion of the first electronic feature in step (c). The encapsulation layer optionally is hydrophobic or hydrophilic.

In one aspect, the first electronic feature comprises a metal, which is oxidized at a slower rate in the encapsulated electronic feature relative to an unencapsulated first electronic feature. Additionally or alternatively, the encapsulating agent comprises an adhesion agent.

In one embodiment, the process further comprises the step of applying a second ink to at least a portion of the encapsulation layer. Additionally, the process optionally further comprises the step of: treating the second ink under conditions effective to form at least a portion of a second electronic feature. Optionally, in this aspect, the first electronic feature comprises a first conductive trace and the second electronic feature comprises a second conductive trace, and the first and second conductive traces are insulated from one another by the encapsulation layer. In another aspect, the process further comprises the step of treating the second ink under conditions effective to form a second portion of the first electronic feature.

In one embodiment, the encapsulating agent is selectively applied to the at least a portion of the first electronic feature in step (c) to form a void in the encapsulation layer, the process further comprising the steps of: applying a via ink to at least a portion of the void; and (e) treating the applied via ink under conditions effective to form a via. In this embodiment, the process optionally further comprises a step of applying a second ink on at least a portion of the encapsulation layer. Additionally, the process may further comprise the step of treating the second ink under conditions effective to form at least a portion of a second electronic feature, the second electronic feature being electrically coupled to the first electronic feature by the via. In a similar aspect, the process optionally further comprises the step of treating the second ink under conditions effective to form a second portion of the first electronic feature, the second portion being electrically coupled by the via to a first portion of the first electronic feature, the first portion being formed by the first ink in step (b). The treating of the applied via ink and the treating of the applied second ink optionally occur simultaneously.

In another embodiment, the invention is to a process for forming a ramp feature, the process comprising the steps of: (a) providing a substrate having a substantially planar surface and a three-dimensional electronic feature disposed on the substantially planar surface, the three-dimensional electronic feature having a connection point disposed longitudinally relative to the substantially planar surface; (b) applying a ramping agent to the substantially planar surface adjacent the electronic feature; and (c) treating the applied ramping agent under conditions effective to form the ramp feature extending angularly, relative to the substantially planar surface, from a first point on the substantially planar surface to the connection point.

In one aspect, the ramping agent comprises a UV curable composition, and step (c) comprises applying UV radiation to the applied ramping agent. Additionally or alternatively, the ramping agent comprises a polymer resin, and step (c) comprises applying a hardener to the ramping agent under conditions effective to form the ramp feature. Additionally or alternatively, the ramping agent comprises a liquid vehicle, and step (c) comprises heating the applied ramping agent under conditions effective to remove a weight majority of the liquid vehicle from the applied ramping agent. In this aspect, the applied ramping agent optionally is heated to a maximum temperature of not greater than about 200° C., not greater than about 150° C. or not greater than about 100° C. In this aspect, the ramping agent optionally further comprises a polymer selected from the group consisting of an acrylic polymer, a polystyrene and a polyurethane.

Additionally, the process optionally further comprises the steps of applying an electronic ink onto at least a portion of the ramp feature; and treating the applied electronic ink under conditions effective to form at least a portion of a second electronic feature on the ramp feature. In this aspect, at least a portion of the second electronic feature preferably contacts the connection point. In one embodiment, the second electronic feature comprises a conductor that electrically couples the first electronic feature with a third electronic feature. The electronic ink optionally comprises a metallic composition, which optionally comprises a metal selected from the group consisting of silver, gold, copper, nickel, cobalt, palladium, platinum, indium, tin, zinc, titanium, chromium, tantalum, tungsten, iron, rhodium, iridium, ruthenium, osmium and lead. Additionally or alternatively, the metallic composition comprises an alloy comprising at least two metals, each of the two metals being selected from the group consisting of silver, gold, copper, nickel, cobalt, palladium, platinum, indium, tin, zinc, titanium, chromium, tantalum, tungsten, iron, rhodium, iridium, ruthenium, osmium and lead. In another aspect, the electronic ink comprises a metal precursor to a metal, the metal being selected from the group consisting of silver, gold, copper, nickel, cobalt, palladium, platinum, indium, tin, zinc, titanium, chromium, tantalum, tungsten, iron, rhodium, iridium, ruthenium, osmium and lead.

In a preferred aspect of the invention, the ramping agent comprises a substantially non-conductive material selected from the group consisting of a dielectric material, a dielectric precursor, glass, silica, titania, alumina, and a silane. Additionally or alternatively, the ramping agent comprises an adhesion agent. The ramping agent preferably has a viscosity of less than about 50 centipoise and optionally a surface tension of from about 10 dynes/cm to about 50 dynes/cm. Accordingly, the ramping agent may be direct write printed onto the at least a portion of the substantially planar surface in step (b). The ultimately formed ramp feature may be hydrophobic or hydrophilic.

In each aspect of the invention, the substrate optionally is selected from the group consisting of a fluorinated polymer, a polyimide, an epoxy resin, a polycarbonate, polyester, polyethylene, polypropylene, polyvinyl chloride, ABS copolymer, wood, paper, metallic foil, glass, flexible fiberboard, non-woven polymeric fabric, and cloth.

In each aspect of the invention, the electronic feature optionally is selected from the group consisting of a conductor, a resistor, a capacitor, an inductor, a dielectric and a semiconductor.

### BRIEF DESCRIPTION OF THE DRAWINGS

The present invention will be better understood in view of the following non-limiting figures, wherein:

FIG. 1 illustrates a first substrate having a first type of surface irregularity;

FIG. 2 illustrates a second substrate having a second type of surface irregularity;

FIG. 3 illustrates a planarizing feature planarizing the first substrate according to one embodiment of the present invention;

FIG. 4 illustrates a planarizing feature planarizing the second substrate according to another embodiment of the present invention;

FIG. 5 illustrates an encapsulated electronic feature according to another embodiment of the present invention;

FIG. 6 illustrates a void formed during an encapsulation process;

FIG. 7 illustrates the formation of a via in the void according to another embodiment of the present invention;

FIG. 8 illustrates the formation of a secondary electronic feature connected to a first electronic feature by the via;

FIG. 9 illustrates a two electronic features having longitudinally spaced connection points;

FIG. 10 illustrates a ramp feature according to another aspect of the invention; and

FIG. 11 illustrates an electronic feature formed on the ramp feature according to another embodiment of the present invention.

### DETAILED DESCRIPTION OF THE INVENTION

I. Introduction

In one aspect, the present invention is directed to processes for planarizing a substrate prior to application of an electronic ink to form a printed electronic feature. As used herein, the term “planarizing” and variations thereof means modifying a substrate surface to make it more planar (e.g., on a microscopic and/or on a macroscopic scale). In one aspect, for example, the process comprises the steps of: (a) providing a first substrate having a first surface, wherein the first surface has a surface irregularity; (b) applying a planarizing agent to at least a portion of the first surface; (c) treating the applied planarizing agent under conditions effective to form the second substrate, the second substrate comprising the first substrate and a planarizing feature formed from the planarizing agent, wherein the second substrate has a planar surface formed at least in part of the planarizing feature, the planar surface being more planar than the first surface; and (d) forming an electronic feature on the planar surface.

In another embodiment, the invention is to a process for encapsulating a printed electronic feature. In one aspect, the process includes the steps of: (a) direct write printing a first ink onto a substrate; (b) treating the first ink under conditions effective to form at least a portion of a first electronic feature; (c) applying an encapsulating agent to the at least a portion of the first electronic feature; and (d) treating the applied encapsulating agent under conditions effective to form an encapsulated electronic feature comprising an encapsulation layer and the at least a portion of the first electronic feature.

In another embodiment, the invention is to a process for forming a ramp feature for electronically coupling a three-dimensional electronic feature with another, longitudinally and laterally spaced, electronic feature. In one aspect, the process includes the steps of: (a) providing a substrate having a substantially planar surface and a three-dimensional electronic feature disposed on the substantially planar surface, the three-dimensional electronic feature having a connection point disposed longitudinally relative to the substantially planar surface; (b) applying a ramping agent to the substantially planar surface adjacent the electronic feature; and (c) treating the applied ramping agent under conditions effective to form the ramp feature extending angularly, relative to the substantially planar surface, from a first point on the substantially planar surface to the connection point.

As used herein, the term “lateral” means a direction substantially parallel to a substrate surface and the term “longitudinal” means a direction substantially perpendicular to the substrate surface. The term “proximal” means the longitudinal direction extending toward the substrate surface, and the term “distal” means the longitudinal direction extending away from the substrate surface.

II. Printable Electronic Features and Processes for Making Printable Electronic Features

Many printable electronic features and processes for making printable electronic features from one or more inks are known and are disclosed in, for example, Published U.S. Patent Application Nos. US2003/0161959 A1 filed on Nov. 1, 2002, US2003/0108664 A1 filed on Oct. 4, 2002, US2003/0124259 A1 filed on Oct. 4, 2002, US2003/0175411 A1 filed on Oct. 4,2002, US2003/0180451 A1 filed on Oct. 4, 2002, and US2003/0148024 A1 filed on Oct. 4, 2002, the entireties of which are incorporated herein by reference. The processes disclosed in the above-referenced patent applications relate to forming various electronic features from one or more electronic inks. As used herein, the term “electronic ink” means an ink suitable for printing, e.g., direct write printing, to form at least a portion of an electronic feature. According to this definition, an electronic ink may or may not allow for the flow of electrons, e.g., be conductive.

In various aspects, the electronic inks used to form printable electronic features may comprise a variety of different compositions. Electronic inks may include, for example, one or more of the following components: liquid vehicles, nanoparticles (metallic or non-metallic), anti-agglomeration agents, metal precursors, reducing agents, one or more additives and/or other components.

Electronic inks typically include a liquid vehicle, which is defined herein as a flowable medium that facilitates deposition of the electronic ink, such as by imparting sufficient flow properties or supporting dispersed particles. The liquid vehicle may act as a solvent to one or more components contained in the first ink and/or as a carrier to one or more particulates, e.g., as an emulsion. In a preferred embodiment, the liquid vehicle comprises a solvent in which the metal precursor is dissolved.

The liquid vehicle may comprise an aqueous-based solvent, an organic solvent or a combination thereof. Aqueous liquids may be preferred for use as the liquid vehicle in many situations because of their low cost, relative safety and ease of use. For example, water has the advantage of being non-flammable, and when vaporized during the formation of the particles does not tend to contribute to formation of byproducts that are likely to complicate processing or contaminate the ultimately resulting conductive features. Moreover, aqueous liquids are good solvents for a large number of metal precursors, although attaining a desired level of solubility for some materials may involve modification of the aqueous liquid, such as pH adjustment.

Optionally, the electronic ink comprises a metallic composition, preferably metallic nanoparticles, defined herein as particles having an average particle size (d50 value) of not greater than about 500 nm, preferably not greater than about 100 nm. In terms of ranges, the nanoparticles optionally have an average particle size of from about 10 to about 80 nm, e.g., from about 25 to about 75 run, and are not substantially agglomerated. The solids loading of particles in the ink optionally is as high as possible without adversely affecting the viscosity or other necessary properties of the ink.

The metallic composition optionally comprises a metal selected from the group consisting of silver, gold, copper, nickel, cobalt, palladium, platinum, indium, tin, zinc, titanium, chromium, tantalum, tungsten, iron, rhodium, iridium, ruthenium, osmium and lead. In another aspect, the metallic composition comprises an alloy comprising at least two metals, each of the two metals being selected from the group consisting of silver, gold, copper, nickel, cobalt, palladium, platinum, indium, tin, zinc, titanium, chromium, tantalum, tungsten, iron, rhodium, iridium, ruthenium, osmium and lead.

In one aspect, the electronic ink comprises nanoparticles, and the electronic ink comprises an anti-agglomeration agent, which inhibits agglomeration of the nanoparticles. Due to their small size and the high surface energy associated therewith, nanoparticles usually show a strong tendency to agglomerate and form larger secondary particles (agglomerates). In one aspect of the invention, the nanoparticles comprise an anti-agglomerating agent, which inhibits agglomeration of the nanoparticles. Preferably, the nanoparticles are coated, at least in part, with the anti-agglomerating agent. The anti-agglomerating agent preferably comprises a polymer, preferably an organic polymer.

In several preferred embodiments, the polymer comprises a polymer of vinylpyrrolidone. More preferably, the polymer of vinylpyrrolidone comprises a homopolymer. In other aspects, the polymer of vinylpyrrolidone comprises a copolymer. The copolymer may be selected from the group consisting of a copolymer of vinylpyrrolidone and vinylacetate; a copolymer of vinylpyrrolidone and vinylimidazole; and a copolymer of vinylpyrrolidone and vinylcaprolactam.

The anti-agglomeration substance shields (e.g., sterically and/or through charge effects) the nanoparticles from each other to at least some extent and thereby substantially prevents a direct contact between individual nanoparticles. The anti-agglomeration substance is preferably adsorbed on the surface of the metallic nanoparticles. The term “adsorbed” as used herein includes any kind of interaction between the anti-agglomeration substance and a nanoparticle surface (e.g., the metal atoms on the surface of a nanoparticle) that manifests itself in an at least (and preferably) weak bond between the anti-agglomeration substance and the surface of a nanoparticle. Preferably, the bond is a non-covalent bond, but still strong enough for the nanoparticle/anti-agglomeration substance combination to withstand a washing operation with a solvent that is capable of dissolving the anti-agglomeration substance. In other words, merely washing the metallic nanoparticles with the solvent at room temperature will preferably not remove more than a minor amount (e.g., less than about 10%, less than about 5%, or less than about 1%) of the anti-agglomeration substance that is in intimate contact with (and (weakly) bonded to) the nanoparticle surface. Of course, any anti-agglomeration substance that is not in intimate contact with a nanoparticle surface but merely accompanies the bulk of the nanoparticles (e.g., as an impurity/contaminant), i.e., without any significant interaction therewith, will preferably be removable from the nanoparticles by washing the latter with a solvent for the anti-agglomeration substance.

In another aspect, the electronic ink comprises a metal precursor to a metal. As used herein, a “metal precursor” is a compound comprising a metal and capable of being converted (e.g., through a reaction with a reducing agent and/or with the application of heat) to form an elemental metal corresponding to the metal in the metal precursor. “Elemental metal” means a substantially pure metal or alloy having an oxidation state of zero. In this aspect, the metal in the metal precursor optionally is selected from the group consisting of silver, gold, copper, nickel, cobalt, palladium, platinum, indium, tin, zinc, titanium, chromium, tantalum, tungsten, iron, rhodium, iridium, ruthenium, osmium and lead.

The electronic ink also optionally comprises a reducing agent to facilitate conversion of a metal in a metal precursor optionally contained in the ink (or derived form another ink) to its elemental form. The use of a reducing agent permits the processing temperature to be maintained below the melting temperature of the substrate, whereas the processing temperature may exceed those limits without use of the reducing agent. In various embodiments, the primary reducing agent is selected from the group consisting of alcohols, aldehydes, amines, amides, alanes, boranes, borohydrides, aluminohydrides and organosilanes.

A non-limiting list of exemplary additives that may be included in the first ink includes: crystallization inhibitors, polymers, polymer precursors (oligomers or monomers), binders, dispersants, surfactants, humectants, defoamers, pigments and the like.

The physical characteristics of electronic inks vary widely depending, for example, on the desired printing process to be used to apply the electronic ink. The inks may be applied to a substrate by a variety of printing processes including intaglio printing, gravure printing, lithographic printing and flexographic printing. Other deposition techniques include roll printer, spraying, dip coating, spin coating, and other techniques that direct discrete units of fluid or continuous jets, or continuous sheets of fluid to a surface. In a preferred aspect, the electronic ink is applied by a direct write printing process, such as ink-jet printing. For ink-jet printing applications, the electronic ink preferably has a viscosity of less than about 100 centipoise, e.g., less than about 50 centipoise or less than about 40 centipoise. The surface tension of the electronic ink for ink-jet applications preferably ranges from about 15 dynes/cm to about 72 dynes/cm (e.g., from about 20 to about 60 dynes/cm or from about 25 to about 50 dynes/cm).

Many processes are known for forming electronic features from the above-described electronic inks. In a preferred embodiment, at least a portion of the electronic feature is formed by a process comprising the steps of: (a) depositing an electronic ink comprising a liquid vehicle onto a substrate surface; and (b) removing the liquid vehicle, e.g., by heating, under conditions effective to form the at least a portion of the electronic feature. Heating rates for drying the electronic ink are preferably greater than about 10° C./min., more preferably greater than about 100° C./min. and even more preferably greater than about 1000° C./min. If the ink comprises metal nanoparticles, the nanoparticles may become sintered or fused together as the liquid vehicle is removed.

In one aspect of the present invention, the deposited electronic ink may be converted to an electronic feature at temperatures of not higher than about 300° C., e.g., not higher than about 250° C., not higher than about 225° C., not higher than about 200° C., or even not higher than about 185° C. In many cases it will be possible to achieve substantial conductivity at temperatures of not higher than about 150° C., e.g., at temperatures of not higher than about 125° C., or even at temperatures of not higher than about 100° C. Any suitable method and device and combinations thereof can be used for the conversion, e.g., heating in a furnace or on a hot plate, irradiation with a light source (ultraviolet (UV) lamp, infrared (IR) or heat lamp, laser, etc.), combinations of any of these methods, to name just a few.

In another embodiment, at least a portion of the electronic feature is formed by a process comprising the steps of: (a) depositing an electronic ink comprising a metal precursor and a liquid vehicle onto a substrate surface; and (b) reacting the metal precursor with a reducing agent under conditions effective to form the at least a portion of the electronic feature.

Non-limiting examples of other methods for processing deposited electronic inks include methods using a UV, IR, laser or a conventional light source. The temperature of the deposited electronic ink can be raised using hot gas or by contact with a heated substrate. This temperature increase may result in further evaporation of vehicle and other species. A laser, such as an IR laser, can also be used for heating. An IR lamp, a hot plate or a belt furnace can also be utilized. It may also be desirable to control the cooling rate of the deposited feature.

Preferred inks according to the present invention can be deposited and converted to electronic features at low temperatures, thereby enabling the use of a variety of substrates having a relatively low softening (melting) or decomposition temperature.

Non-limiting examples of substrates that are particularly advantageous according to the present invention include substrates comprising one or more of FR4, fluorinated polymer, polyimide, epoxy resin (including glass-filled epoxy resin), polycarbonate, polyester, polyethylene, polypropylene, polyvinyl chloride, ABS copolymer, synthetic paper, flexible fiberboard, non-woven polymeric fabric, cloth and/or other textiles. Other particularly advantageous substrates include cellulose-based materials such as wood or paper, and metallic foil and glass (e.g., thin glass). The substrate may be coated. Although the inks can be used particularly advantageously for temperature-sensitive substrates, it is to be appreciated that other substrates such as, e.g., metallic and ceramic substrates can also be used in accordance with the present invention.

Of particular interest for display applications are glass substrates and indium tin oxide (ITO) coated glass substrates. Other glass coatings that the metal features may be printed on in flat panel display applications include semiconductors such as c-Si on glass, amorphous Si on glass, poly-Si on glass, and organic conductors and semiconductors printed on glass. The glass may also be substituted with, e.g., a flexible organic transparent substrate such as PET or PEN. The metal or alloy (e.g., Ag) may also be printed on top of a black layer or coated with a black layer to improve the contrast of a display device. Other substrates of particular interest include printed circuit board substrates such as FR4, textiles including woven and non-woven textiles.

Another substrate of particular interest is natural or synthetic paper, in particular, paper that has been coated with specific layers to enhance gloss and accelerate the infiltration of ink solvent or liquid vehicle. A preferred example of a glossy coating for ink-jet paper includes alumina nanoparticles such as fumed alumina in a binder. Also, a silver ink according to the present invention that is ink-jet printed on EPSON glossy photo paper and heated for about 30 min. at about 100° C. is capable of exhibiting highly conductive Ag metal lines with a bulk conductivity in the 10 micro-Ω cm range.

According to a preferred aspect of the present invention, the substrate onto which the electronic ink is deposited may have a softening and/or decomposition temperature of not higher than about 225° C., e.g., not higher than about 200° C., not higher than about 185° C., not higher than about 150° C., or not higher than about 125° C.

The electronic features ultimately formed from the electronic inks may vary widely. For example, the electronic feature may comprise a passive feature such as a conductor, a resistor, a dielectric, an inductor, a ferromagnetic, or a capacitor. In other aspects, the electronic feature comprises an active feature such as a transistor, a sensor, a display device, or a memory device (e.g., a ROM device). The present invention is also applicable to inductor-based devices including transformers, power converters and phase shifters. Examples of such devices are illustrated in, e.g., U.S. Pat. Nos. 5,312,674; 5,604,673 and 5,828,271, the entire disclosures whereof are incorporated by reference herein.

In one aspect, the electronic features optionally are in the form of lines. In one aspect, the lines can advantageously have an average width of not greater than about 250 μm, such as not greater than about 200 μm, not greater than about 150 μm, not greater than about 100 μm, or not greater than about 50 μm.

III. Planarizing Agent, Encapsulating Agent and Ramping Agent Compositions

As discussed in more detail below, in various embodiments, the present invention is directed to planarizing a substrate, encapsulating an electronic feature and forming a ramp feature on a substrate. Each of these processes, respectively, comprises a step of applying and treating a planarizing agent, an encapsulating agent or a ramping agent. The various possible compositions of each of the planarizing agent, the encapsulating agent and the ramping agent (as well as of the ultimately formed planarizing feature, encapsulation layer and ramping feature) are substantially identical to one another, except where otherwise indicated herein. Accordingly, for the sake of brevity, this section of the present specification refers to possible planarizing agent compositions for forming a planarizing feature, although it will be understood that the disclosed compositions also disclose possible compositions of the encapsulating agents and/or the ramping agents of the present invention.

The composition and properties of the planarizing agent will vary widely depending on the application process selected and the desired properties for the ultimately formed planarizing feature. To be suitable for ink-jet application, the planarizing agent preferably has a viscosity of less than about 100 centipoise, e.g., less than about 50 centipoise or less than about 40 centipoise. The surface tension of the planarizing agent for ink-jet applications preferably ranges from about 15 dynes/cm to about 72 dynes/cm (e.g., from about 20 to about 60 dynes/cm or from about 25 to about 50 dynes/cm).

It is preferred that the planarizing feature be substantially non-conductive (e.g., formed of a dielectric material) so that it does not interfere with any electronic features associated therewith. Accordingly, the planarizing agent (which ultimately is converted to the planarizing feature) comprises one or more of the following components: a liquid vehicle, dielectric particulates (e.g., nanoparticles), a dielectric precursor, a polymer, a monomer, and/or one or more additives. 1. Liquid Vehicle

Typically, the planarizing agent will include a liquid vehicle, which is defined herein as a flowable medium that facilitates deposition of the ink, such as by imparting sufficient flow properties or supporting dispersed particles. The liquid vehicle may act as a solvent to one or more components contained in the planarizing agent and/or as a carrier to one or more particulates, e.g., as an emulsion. In a preferred embodiment, the liquid vehicle comprises a solvent in which a dielectric precursor is dissolved.

The liquid vehicle may comprise an aqueous-based solvent, an organic solvent or a combination thereof. Aqueous liquids may be preferred for use as the liquid vehicle in many situations because of their low cost, relative safety and ease of use. For example, water has the advantage of being non-flammable, and when vaporized during the formation of the particles does not tend to contribute to formation of byproducts that are likely to complicate processing or contaminate the ultimately resulting conductive features. Moreover, aqueous liquids are good solvents for a large number of metal precursors, although attaining a desired level of solubility for some materials may involve modification of the aqueous liquid, such as pH adjustment.

The liquid vehicle can also include an organic solvent, by itself or in addition to water. The selected solvent optionally is capable of solubilizing a dielectric precursor in the planarizing agent to a high level. A low solubility of the dielectric precursor in the solvent may lead to low yields of the ultimately formed planarizing agent, thin deposits and poor planarization. In one aspect, the planarizing agent of the present invention exploits combinations of solvents and dielectric precursors that advantageously provide high solubility of the dielectric precursors while still allowing low temperature conversion of the precursor to the planarizing feature.

The liquid vehicle (e.g., solvent and/or carrier composition) can be polar or non-polar. Solvents that are useful according to the present invention include amines, amides, alcohols, water, ketones, unsaturated hydrocarbons, saturated hydrocarbons, mineral acids organic acids and bases. Preferred solvents include alcohols, amines, amides, water, ketones, ethers, aldehydes and alkenes. Particularly preferred organic solvents according to the present invention include N,N,-dimethylacetamide (DMAc), diethyleneglycol butylether (DEGBE), ethanolamine and N-methyl pyrrolidone.

In some cases, the liquid vehicle can be a high melting point liquid vehicle, such as one having a melting point of at least about 30° C. and not greater than about 100° C. In this embodiment, a heated ink-jet head can be used to deposit the planarizing agent while in a flowable state whereby the liquid vehicle solidifies upon contacting the substrate. Subsequent processing can then remove the liquid vehicle by other means and then convert the material to the final product, thereby retaining resolution. Preferred liquid vehicles according to this embodiment are waxes, high molecular weight fatty acids, alcohols, acetone, N-methyl-2-pyrrolidone, toluene, tetrahydrofuran and the like. Alternatively, the liquid vehicle may be a liquid at room temperature, wherein the substrate is kept at a lower temperature below the freezing point of the composition.

The liquid vehicle can also be a low melting point liquid vehicle. A low melting point is required when the precursor composition must remain as a liquid on the substrate until dried. A preferred low melting point liquid vehicle according to this embodiment is DMAc, which has a melting point of about −20° C.

In addition, the liquid vehicle can be a low vapor pressure solvent. A lower vapor pressure advantageously prolongs the work life of the composition in cases where evaporation in the ink-jet head, syringe or other tool leads to problems such as clogging. A preferred liquid vehicle according to this embodiment is terpineol. Other low vapor pressure liquid vehicles include diethylene glycol, ethylene glycol, hexylene glycol, N-methyl-2-pyrrolidone, glycerol, 2-pyrolidone, polyethylene glycols, and tri(ethylene glycol) dimethyl ether.

The liquid vehicle can also be a high vapor pressure solvent, such as one having a vapor pressure of at least about 1 kPa. A high vapor pressure allows rapid removal of the solvent by drying. High vapor pressure liquid vehicles include acetone, tetrahydrofuran, toluene, xylene, ethanol, methanol, isopropanol, 2-butanone and water.

The amount of liquid vehicle in the first ink may vary depending, for example, on the solubility of the optional dielectric precursor in the liquid vehicle. In other embodiments, the amount of vehicle in the planarizing agent may vary depending, for example, on the size of the particles in the ink, if any, and on the desired viscosity of the planarizing agent. As non-limiting examples, the planarizing agent optionally comprises the liquid vehicle (e.g., solvent and/or carrier medium) in an amount from about 20 to about 99 weight percent, e.g., from about 30 to about 95 weight percent or from about 40 to about 70 weight percent, based on the total weight of the first ink.

Examples of ink-jet liquid vehicle compositions are disclosed in U.S. Pat. No. 5,853,470 by Martin et al.; U.S. Pat. No. 5,679,724 by Sacripante et al.; U.S. Pat. No. 5,725,647 by Carlson et al.; U.S. Pat. No. 4,877,451 by Winnik et al.; U.S. Pat. No. 5,837,045 by Johnson et al.; and U.S. Pat. No. 5,837,041 by Bean et al. Each of the foregoing U.S. patents is incorporated by reference herein in their entirety. Examples of preferred vehicles are listed in Table 1. Particularly preferred vehicles according to the present invention include alpha terpineol, toluene and ethylene glycol.

TABLE 1
LIQUID VEHICLES

| FORMULA/CLASS | NAME |
|---|---|
| Alcohols | 2-octanol |
| | Benzyl alcohol |
| | 4-hydroxy-3-methoxy benzaldehyde |
| | Isodeconol |
| | Isopropanol |
| | Glycerol |
| | Ethanol |
| | Ethylene glycol |
| | Butylcarbitol |
| Turpene alcohol | Alpha terpineol |
| | Beta terpineol |
| | Cineol |
| Esters | 2,2,4-trimethylpentanediol-1,3- |
| | monoisobutyrate |
| | Butyl carbitol acetate |
| | Butyl oxalate |
| | Dibutyl phthalate |
| | Dibutyl benzoate |
| | Butyl cellosolve acetate |
| | Ethylene glycol diacetate |
| | N-methyl-2-pyrolidone |
| Amides | N,N-dimethyl formamide |
| | N,N-dimethyl acetamide |
| Aromatics | Xylenes |
| | Aromasol |
| Substituted aromatics | Nitrobenzene |
| | o-nitrotoluene |
| Terpenes | Alpha-pinene, beta-pinene dipentene |
| | dipentene oxide |
| Essential oils | Rosemary, lavender, fennel, sassafras, |
| | wintergreen, anise oils, camphor, |
| | turpentine |

2. Dielectric Particulates and Precursors

The planarizing feature ultimately formed from the planarizing agent preferably comprises a substantially non-conductive material so that the planarizing feature will not interfere, electronically, with previously and/or subsequently applied electronic features. In one aspect, the substantially non-conductive material is selected from the group consisting of a dielectric material, for example, glass, silica, titania, or alumina. Accordingly, the planarizing agent used to form the planarizing feature preferably comprises one or more of these materials and/or a precursor to one or more of these materials.

In one aspect, the planarizing agent comprises particulates, e.g., dielectric particulates. For example, the planarizing agent optionally comprises dielectric nanoparticles (having an average particle size less than 500 nm). In one embodiment, the planarizing agent comprises dielectric nanoparticles selected from the group consisting of: glass nanoparticles, silica (SiO₂) nanoparticles, titania (TiO₂) nanoparticles, and alumina (Al₂O₃) nanoparticles. Other useful nanoparticles that may be included in the planarizing agent include pyrogenous silica such as HS-5 or M5 or others (Cabot Corp., Boston, Mass.) and AEROSIL 200 or others (Degussa A G, Dusseldorf, Germany) or surface modified silica such as TS530 or TS720 (Cabot Corp., Boston, Mass.) and AEROSIL 380 (Degussa A G, Dusseldorf, Germany). Other dielectric compositions that may be included in the planarizing agent are disclosed in Published U.S. Patent Application US2004/017541 1 Al to Kodas et al., filed on Oct. 4, 2002, the entirety of which is incorporated herein by reference. In other embodiments, the dielectric particulates comprise one or more metal oxides, e.g., copper oxides (CuOₓ)

In this aspect, the solids loading of the planarizing agent preferably is as high as possible without adversely affecting the deposition properties of the planarizing agent, e.g., maintaining adequate ink-jet deposition properties. In preferred aspects, the total loading of dielectric nanoparticles in the planarizing agent is not higher than about 75% by weight, such as from about 5% by weight to about 60% by weight, based on the total weight of the planarizing agent. Loadings in excess of the preferred amounts can lead to undesirably high viscosities and/or undesirable flow characteristics. Of course, the maximum loading which still affords useful results also depends on the density of the dielectric material in the nanoparticles. In other words, the higher the density of the dielectric material of the nanoparticles, the higher will be the acceptable and desirable loading in weight percent. In preferred aspects, the nanoparticle loading is at least about 10% by weight, e.g., at least about 15% by weight, at least about 20% by weight, or at least about 40% by weight. Depending on the dielectric material, the loading will often not be higher than about 65% by weight, e.g., not higher than about 60% by weight. These percentages refer to the total weight of the nanoparticles, i.e., including any anti-agglomeration substance carried (e.g., adsorbed) thereon.

According to a preferred aspect of the present invention, the dielectric nanoparticles exhibit a narrow particle size distribution. A narrow particle size distribution is particularly advantageous for direct-write applications because it results in a reduced clogging of the orifice of a direct-write device by large particles and provides the ability to form features having a fine line width, high resolution and high packing density.

The dielectric nanoparticles for use in the present invention preferably also show a high degree of uniformity in shape. Preferably, the dielectric nanoparticles are substantially spherical in shape. Spherical particles are particularly advantageous because they are able to disperse more readily in a liquid suspension and impart advantageous flow characteristics to the planarizing agent, particularly for deposition using an ink-jet device or similar tool. For a given level of solids loading, a low viscosity planarizing agent having spherical particles will have a lower viscosity than a composition having non-spherical particles, such as flakes. Spherical particles are also less abrasive than jagged or plate-like particles, reducing the amount of abrasion and wear on the deposition tool.

In a preferred aspect of the present invention, at least about 90%, e.g., at least about 95%, or at least about 99% of the dielectric nanoparticles comprised in the planarizing agent are substantially spherical in shape. In another preferred aspect, the planarizing agent is substantially free of particles in the form of flakes.

In yet another preferred aspect, the particles are substantially free of micron-size particles, i.e., particles having a size of about 1 micron or above. Even more preferably, the nanoparticles may be substantially free of particles having a size (=largest dimension, e.g., diameter in the case of substantially spherical particles) of more than about 500 nm, e.g., of more than about 200 nm, or of more than about 100 nm. In this regard, it is to be understood that whenever the size and/or dimensions of the nanoparticles are referred to herein and in the appended claims, this size and these dimensions refer to the nanoparticles without anti-agglomeration substance thereon, e.g., the metal cores of the nanoparticles. Depending on the type and amount of anti-agglomeration substance, an entire nanoparticle, e.g., a nanoparticle which has the anti-agglomeration substance thereon, may be significantly larger than the metal core thereof. Also, the term “nanoparticle” as used herein and in the appended claims encompasses particles having a size/largest dimension of the metal cores thereof of up to about 900 nm, preferably of up to about 500 nm, more preferably up to about 200 nm, or up to about 100 nm.

By way of non-limiting example, not more than about 5%, e.g., not more than about 2%, not more than about 1%, or not more than about 0.5% of the dielectric nanoparticles may be particles whose largest dimension (and/or diameter) is larger than about 200 nm, e.g., larger than about 150 nm, or larger than about 100 run. In a particularly preferred aspect, at least about 90%, e.g., at least about 95%, of the dielectric nanoparticles will have a size of not larger than about 80 nm and/or at least about 80% of the dielectric nanoparticles will have a size of from about 20 nm to about 70 nm. For example, at least about 90%, e.g., at least about 95% of the nanoparticles may have a size of from about 30 nm to about 50 nm.

In another aspect, the dielectric nanoparticles may have an average particle size (number average) of at least about 10 nm, e.g., at least about 20 nm, or at least about 30 nm, but preferably not higher than about 80 nm, e.g., not higher than about 70 nm, not higher than about 60 nm, or not higher than about 50 nm. For example, the dielectric nanoparticles may have an average particle size in the range of from about 25 nm to about 75 nm.

In yet another aspect of the present invention, at least about 80 volume percent, e.g., at least about 90 volume percent of the dielectric nanoparticles may be not larger than about 2 times, e.g., not larger than about 1.5 times the average particle size (volume average).

The nanoparticles that are useful in planarizing agents according to the present invention preferably have a high degree of purity. For example, the particles (without anti-agglomeration substance) may include not more than about 1 atomic percent impurities, e.g., not more than about 0.1 atomic percent impurities, preferably not more than about 0.01 atomic percent impurities. Impurities are those materials that are not intended in the final product (e.g., the planarizing feature) and that adversely affect the properties of the final product. For planarizing applications, the most critical impurities to avoid are conductive impurities.

Additionally or alternatively, the planarizing agent optionally comprises dielectric microparticles (having an average particle size at least about 0.1 μm and less than 500 μm). Preferred compositions of micron-size particles are similar to the compositions described above with respect to dielectric nanoparticles. The particles are preferably spherical, such as those produced by spray pyrolysis. Particles in the form of flakes increase the viscosity of the precursor composition and are not amenable to deposition using tools having a restricted orifice size, such as an ink-jet device. When substantially spherical particles are described herein, the particle size refers to the particle diameter. In one preferred embodiment, the low viscosity precursor compositions according to the present invention do not include any particles in the form of flakes.

Generally, the volume median particle size of the micron-size particles utilized in the planarizing agent according to the present invention is at least about 0.1 μm, such as at least about 0.3 μm. Further, the volume median particle size is preferably not greater than about 2 μm. For most applications, the volume median particle size is more preferably not greater than about 10 μm and even more preferably is not greater than about 5 μm. A particularly preferred median particle size for the micron-size particles is from about 0.3 μm to about 3 μm. According to one embodiment of the present invention, it is preferred that the volume median particle size of the micron-size particles is at least 10 times smaller than the orifice diameter in the tool applying the planarizing agent, such as not greater than about 5 μm for an ink-jet head having a 50 μm orifice.

Particularly preferred compositions for high dielectric constant powders are those having the perovskite structure. Examples include metal titanates, metal zirconates, metal niobates, and other mixed metal oxides. Particularly useful is the barium titanate system which can reach a broad range of dielectric performance characteristics by adding small levels of dopant ions. Specific examples include BaTiO₃, PbTiO₃, PbZrO₃, PbZrₓTi₁₋ₓO₃ and PbMg_{1/3}Nb_{2/3}O₃.

Particularly preferred compositions for low loss dielectric constant powders are Zr_{0.7}Sn_{0.3}TiO₄, Zr_{0.4}Sn_{0.66}Ti_{0.94}O₄, CaZr_{0.98}Ti_{0.02}O₃, SrZr_{0.94}Ti_{0.06}O₃, BaNd₂Ti₅O₃, Pb₂Ta₂O₇, and various other pyrochlores.

The dielectric precursor compositions of the present invention uniquely allow for the use of two or more different particles, such as by mixing Al₂O₃ and TiO₂ particles, or barium titanate and lead zirconate titanate (PZT) particles. These compositions will not interdiffuse significantly during firing below 600° C., preserving their unique dielectric properties. These compositions can be tailored to have a very low TCC value combined with very low loss.

Preferred glass compositions are low melting temperature glasses, such as borosilicate glasses doped with lead or bismuth. The preferred average particle size for the glass powder is no larger than the other particles present, and more preferably is less than about half the size of the other particles.

The preferred average particle size of the low melting glass particles is on the order of the size of the dielectric particles, and more preferably is about one-half the size of the dielectric particles, and most preferably is about one quarter the size of the dielectric particles.

A bimodal size distribution of particles enhances the packing density and is desired to increase the performance, preferably with the smaller particles being about 10 wt. % of the total mass of powder.

As indicated above, the planarization agent optionally includes one or more anti-agglomeration agents, which inhibit agglomeration of the particles (e.g., dielectric nanoparticles) also contained in the planarization agent. The anti-agglomeration agent may include one or more polymers, dispersants, copolymers, homopolymers, or binders.

Additionally or alternatively, the planarizing agent comprises one or more dielectric precursors, defined herein as compositions in the planarizing agent that may be converted, physically or chemically, to a dielectric feature in the ultimately formed planarizing feature. Preferably, the dielectric precursor in the planarizing agent is a precursor to a composition selected from the group consisting of a dielectric material, glass, silica, titania, alumina and a silane.

In a preferred embodiment, the planarizing agent comprises spin on glass. Spin on glass (SOG) is a mixture of SiO₂ and dopants (either boron or phosphorous) that is suspended in a solvent solution.

The amount of dielectric precursor in the planarizing agent may vary widely depending, for example, on the type of desired application process, the relative amount of the dielectric material in entire dielectric precursor and other factors. In various embodiments, the planarizing agent optionally comprises the dielectric material in dielectric precursor in an amount greater than about 1 weight percent, e.g., greater than about 5 weight percent or greater than about 10 weight percent, based on the total weight of the planarizing agent. In terms of upper range limits, the planarizing agent optionally comprises the dielectric material in dielectric precursor in an amount less than about 75 weight percent, e.g., less than about 50 weight percent or less than about 30 weight percent, based on the total weight of the planarizing agent. In terms of ranges, the planarizing agent optionally comprises the dielectric material in the dielectric precursor in an amount from about I to about 50 weight percent, e.g., from about 5 to about 30 or from about 10 to about 20 weight percent, based on the total weight of the planarizing agent.

Many highly insulative (high K) dielectric compositions (and precursors to such compositions) contain barium. When processed in air, barium precursors are susceptible to formation of barium carbonate. Once barium carbonate is formed, it cannot be converted to an oxide below 1000° C. Therefore, barium carbonate formation should be avoided. It is also known that hydroxyl groups are an important source of loss in dielectric metal oxides and the condensation reactions to convert metal hydroxides to metal oxides are not complete until about 800° C. (for isolated surface hydroxyl groups). The present invention includes precursor compositions that avoid hydrolytic-based chemistry such as sol-gel-based hydrolysis and condensation routes.

For planarizing features having low dielectric loss and high dielectric constant, the incorporation of porosity may be detrimental to the performance of these layers as a result of the high internal surface area and the contribution of the dielectric properties of the material trapped inside the pores, especially air. Therefore, porosity typically should be reduced to a minimum.

The metal oxide phases that lead to the desired dielectric properties also may require that the material be highly crystalline. The desired metal oxides do not crystallize until a high temperature and so a method that relies on a low temperature precursor composition that only includes a molecular precursor to the final phase will have both a low material yield and poor crystallinity. Conversely, a composition and method relying on only particulate material will likely provide high porosity if processed below 300° C.

The present invention includes dielectric precursor compositions that address these issues and can be converted at low temperatures to form high performance dielectric features. The compositions can include a large volume and mass fraction of highly crystalline, high performance dielectric powder such as BaTiO₃ or BaNd₂Ti₅O₁₄ that has the desired dielectric constant, has a low temperature coefficient and has a low loss. The precursor composition can include a smaller fraction of precursor to another material for which precursors are available that have the following characteristics: (1) avoid the intermediate formation of hydroxyl groups; (2) have ligands that react preferentially to give a single-phase complex stoichiometry product rather than a mixture of a number of different crystalline phases; (3) can be processed to form a crystalline phase at low temperatures; (4) have high ceramic yield; and (5) which result in a good K, low loss and small temperature coefficient contribution. An example of such a target phase is TiO₂ or Zr_{0.40}Sn_{0.66}Ti_{0.94}O₂.

One embodiment of the present invention utilizes novel combinations of molecular precursors that provide lower reaction temperatures than can be obtained through individual precursors. The precursors can include molecules that can be converted to metal oxides, glass-metal oxide, metal oxide-polymer, and other combinations. The dielectric precursor compositions of the present invention can include novel combinations of precursors that provide lower reaction temperatures to form dielectric features than can be obtained through the use of individual precursors. An example of one such combination is Sn—, Zr—, and Ti-oxide precursors.

Depending on their nature, the dielectric precursors can react in the following ways:

Hydrolysis/Condensation
M(OR)ₙ+H₂O→[MOₓ(OR)ₙ₋ₓ]+MO_{y}

Anhydride Elimination
M(OAc)ₙ→[MOₓ/2(OAc)ₙ₋ₓ]+x/2Ac₂O→MO_{y}+n-xAc₂O

Ether Elimination
M(OR)ₙ+[MOₓ(OR)ₙ₋ₓ]+R₂O→MO_{y}+n-xR₂O

Ketone Elimination
M(OOCR)(R′)→MO_{y}+R′RCO

Ester Elimination
M(OR)ₙ+M′(OAc)ₙ→[MM′Oₓ(OAC)ₙ₋ₓ(OR)ₙ₋ₓ]+ROAc
[MM′Oₓ(OAC)ₙ₋ₓ(OR)ₙ₋ₓ]→MM′O_{y}+n-xROAc

Alcohol-Induced Ester Elimination
M(OAc)ₙ+HOR+[MOₓ(OAc)ₙ₋ₓ]→MO_{y}

Small Molecule-Induced Oxidation
M(OOCR)+Me₃NO→MO_{y}+Me₃N+CO₂

Alcohol-Induced Ester Elimination
MO₂CR+HOR→MOH+RCO₂R (ester)
MOH→MO₂

Ester Elimination
MO₂CR+MOR→MOM+RCO₂R (ester)

Condensation Polymerization
MOR+H₂O→(MₐO_{b})OH+HOR
(MₐO_{b})OH+(MₐO_{b})OH→[(MₐO_{b})O(MₐO_{b})O]

A particularly preferred approach is ester elimination, including a sol-gel process utilizing alcohol ester elimination. One preferred combination of precursors according to the present invention is Sn-ethylhexanoate, Zr-ethylhexanoate and dimethoxy titanium neodecanoate. These precursors can be advantageously used in an organic based precursor composition. In this case, the presence of metal alkoxides precludes the use of water. The nature and the ratio of the ligands used in these precursors are critical to achieve a low conversion temperature. Generally, small ligands that can escape cleanly without leaving carbon residue during conversion are preferred. For example, this can be achieved by formation of ethers from alkoxide ligands or by formation of anhydrides from carboxylates. Another preferred combination is the use of a mixed ligand system such as a carboxylate and an alkoxide that can be bound to either the same or different metal centers. Upon conversion, the metal oxygen bonds are broken and small molecules are eliminated. A carboxylate to alkoxide ratio of about 1:1 is particularly preferred because of the formation of organic esters at lower temperatures.

In accordance with the foregoing, useful precursors (where metal=Sn, Zr, Ti, Ba, Ca, Nd, Sr, Pb, Mg) include:

(1) Metal alkoxides, such as Sn-ethoxide, Zr-propoxide, Pb-butoxide, Pb-isopropoxide, Sn-neodecanoate;

(2) Metal carboxylates, such as metal fluorocarboxylates, metal chlorocarboxylates, metal hydroxocarboxylates. Specific examples include Ba-acetate, Sn-ethylhexanoate, and Pb-carboxylates such as Pb-acetate, Pb-trifluoroacetate and Pb-ethylhexanoate;

(3) Metal betadiketonates, including Pb-betadiketonates such as Pb-acetylacetonate and Pb-hexafluoroacetylacetonate; and

(4) Mixed alkoxo metal carboxylates (where metal=Sn, Zr, Ti, Ba, Ca, Nd, Sr, Pb, Mg) such as dimethoxy titanium neodecanoate. Dialkoxo titanium dicarboxylate precursors in the dielectric precursor compositions can also serve as an adhesion promoter.

A dielectric precursor composition can include a dielectric powder and a precursor to an insulative phase. Alternatively, the dielectric precursor can include an insulative powder and a precursor to a dielectric phase. Preferred dielectric powders (nanoparticles or micron-size particles) include BaTiO₃, lead manganese niobate (PMN), lead zirconium titanate (PZT), doped barium titanate (BTO), barium neodymium titanate (BNT), lead tantalate (Pb₂Ta₂O₇), and other pyrochlores. Preferred insulative powders include TiO₂, SiO₂, and insulating glasses. Preferred insulative phase precursors include organic titanates such as titanium bis(ammonium lactato) dihydroxide; mixed alkoxo titanium carboxylates such as dimethoxy titanium bis(neodecanoate) or dibutoxy titanium bis(neodecanoate); silicon alkoxides such as silicon methoxide and silicon ethoxide. Preferred dielectric phase precursors include metal alkoxides, carboxylates and beta-diketonates to form the mixed metal oxide as listed above.

Another consideration when using precursor compositions containing dielectric particles that are formulated to be converted at a low temperature is that the particles should possess properties close to the final desired physical properties of the fully processed devices. Optimization of the intrinsic properties of the particles is crucial because recrystallization and annealing of crystal defects during thermal processing is often not possible at processing temperatures of less than 500° C. Maximization of dielectric constant in the final material requires maximization of the dielectric constant of the powders because the composition is subjected to low temperatures for short times, which are insufficient to increase the crystallinity of the high K powder during processing.

In one embodiment, the precursor composition utilizes dielectric powders with dielectric constants (K) preferably greater than 500 and more preferably greater than 1000. The dielectric constant of the powder can be measured as follows: A pellet is pressed from the dry powder and calcined at 400° C. for one hour to drive off water. The pellet is then placed between metal electrodes and the capacitance is measured as a parallel plate capacitor, over the frequency range of 1 kHz to 1 MHz. Based on the geometry and packing density, the logarithmic rule of mixtures is applied, assuming the two phases present are the powder and air, and the dielectric constant of the powder alone is calculated.

In another embodiment, a precursor composition utilizes dielectric powders with dielectric constants greater than 2000. Such high dielectric constant can be obtained in a powder in various ways. One way is the use of spray pyrolysis, which allows for the addition of dopant in each individual particle. Another way is the use of annealing of particle beds at elevated temperatures such as 900° C. to 1000° C. to improve particle composition and particle crystallinity followed by milling to break up any soft agglomerations formed during firing. A rotary calcine can be used to anneal and limit particle agglomeration.

In another embodiment, a precursor composition includes low loss dielectric powders having a loss of less than 1%, more preferably less than 0.1%, and most preferably less than 0.01%, over the frequency range of 1 kHz to 1 MHz. The dielectric loss can be measured as follows: A pellet is pressed from the dry powder and calcined at 400° C. to drive off surface water. Once the pellet has been dried, it is kept in a dry environment. The pellet is then placed between electrodes and the loss measured as a parallel plate capacitor over the frequency range of 1 kHz to 1 MHz.

In another embodiment, a precursor composition utilizes high-K or low loss dielectric powders as described above, where the particles are exposed to a liquid surface modification agent, such as a silanating agent. The purpose of this treatment is the elimination of surface defects such as hydroxyl groups that induce dielectric loss and/or sensitivity to humidity in the final low-fired dielectric layer. The silanating agent can include an organosilane. For example, a surface-modifying agent is exposed as a gas in a confined enclosure to the powder bed and allowed to sit for about 15 minutes at 120° C., completing the surface modification.

Useful organosilanes include RₙSiX(₄₋ₙ), where X is a hydrolysable leaving group such as an amine (e.g., hexamethyldisilazane), halide (e.g., dichlorodimethylsilane), alkoxide (e.g., trimethoxysilane, methacryloxypropyltrimethoxysilane, N-methyl-3-aminopropyltrimethoxysilane), or acyloxy (e.g., acryloxytrimethylsilane).

Hydrolysis and condensation can occur between organosilane and surface hydroxy groups on the dielectric particle surface. Hydrolysis occurs first with the formation of the corresponding silanol followed by condensation with hydroxo groups on the metal oxide surface. As an example:
R—(CH₂)₃Si(OMe)₃+H₂O→R—(CH₂)₃Si(OH)₂(OMe)₂+2MeOH
R—(CH₂)₃Si(OH)₂(OMe)₂+(particle_{surf}Si)OH→(particle_{surf}Si)—O—Si(OH)₂(CH₂)₃—R+H₂O
where
R═CH₂CCH₃COO

The present invention provides dielectric precursor compositions capable of forming combinations of high k particles and matrix derived from a precursor or a low melting glass or both. Preferred particles for high k materials are lead magnesium niobate (PMN, PbMg_{1/3}Nb_{2/3}O₃), PbTiO₃ (PT), PMN-PT, PbZrₓTi₁₋ₓO (PZT), and doped BaTiO₃. Preferred particles for low loss applications are barium neodymium titanate (BNT, BaNd₂Ti₅O₁₄), zirconium tin titanate (ZST, Ti_{0.94}Zr_{0.4}Sn_{0.66}O₄), lead tantalate (Pb₂Ta₂O₇). Preferred glass compositions are low melting sealing glasses with a melting point below 500° C., more preferably below 400° C., even more preferably below 300° C. Preferred low melting glass particles for high K compositions have high dielectric constants, typically in the range from 10 to 40, more preferably higher than 40. Preferred low melting glass particles for high k compositions have low dielectric loss characteristics, preferably not greater than 2%, more preferably not greater than 1%, even more preferably not greater than 0.1%.

There are essentially two routes to formation of dielectric materials according to the present invention: a precursor plus powders approach, and a powders only approach. Ceramic products that are desirably formed using a precursor plus powder method include: BaTiO₃—PbZrₓTi₁₋ₓO, BaTiO₃—TiO₂, BaTiO₃—TiZrₓSn₁₋ₓO₄, BaNd₂Ti₅O₁₄—TiZrₓSn₁₋ₓO₄. These basic building blocks may be enhanced by the application of surface modification (silanation), or the addition of low melting temperature glass.

The precursor-based approach for dielectrics requires the combination of a dielectric powder with a precursor to a dielectric. The general approach is to first disperse the dielectric powder in a low boiling point solvent. The precursor is then added to the dispersion and most of the solvent is removed, leaving a thick precursor consisting of particles and precursor with a trace amount of solvent. This precursor can then be deposited on a substrate by a variety of methods and fired to yield a novel structure of dielectric particles connected by a dielectric formed from precursor decomposition.

An approach exploiting low melting glasses (LTG) is desirable for: BaTiO₃—LTG, BaNd₂Ti₅O₁₄-LTG and PbMg_{1/3}Nb_{2/3}O₃-LTG. The glass-based approach combines a low melting point glass with one or more dielectric powders. For this approach to be successful the particle size of the glass phase is critical. If the glass particles are larger than the dielectric powder, they will either pool when melted, forming inhomogeneities, or they will wick into the porous arrangement of dielectric particles leaving behind voids.

The general approach in one aspect of the present invention is to coat the powders with a dispersant while in a vehicle then remove the vehicle. The coated powders are then combined in the desired ratio and milled with a solvent and binder system. The desired ratio of glass to particles will vary by application and desired final properties, but will be governed by the following criteria. The dielectric phase is targeted to occupy the majority of the final composite depending on the particle size distribution of the powder. For example, a monomodal powder would be targeted to occupy 63% of the composite. The glass phase is then targeted to occupy the remaining volume, in the example here, 37%. This calculation provides the minimum glass loading and there may be some applications where more glass is used.

In one aspect, the dielectric precursor compositions of the present invention are based on optimizing the dielectric performance of a multiphase composite by combining the phases in the best possible way. The traditional route to high performance dielectrics is dominated by sintering of ceramics at high temperatures, which eliminates porosity and allows for high degrees of crystallization, which yield high performance. When processing at low temperatures, sintering will not occur and other methods must be employed to achieve the best performance. One route to accomplish this is to densely pack dielectric powders and fill the remaining voids with another component. This route has been used in polymer thick film by using a polymer to fill the voids. The dielectric constant of a composite follows a logarithmic mixing rule:
log K=Σ(Vᵢ)log Kᵢ,
where the log of the dielectric constant of the composite is a sum of the dielectric constants of the phases (Kᵢ) multiplied by their volume fractions (Vᵢ). Filling the voids with a low dielectric constant material, for example a polymer, would dramatically reduce the dielectric constant of the composite. For example, if a dielectric powder with a dielectric constant of 5000 is packed to a density of 60% and the remaining volume is filled with a polymer having a dielectric constant of 4, the resulting dielectric constant of the composite is 289. This equation leads to two pursuable routes to maximizing the dielectric constant. One is to maximize the volume fraction of the high dielectric constant particles, and the other is to increase the dielectric constant of the matrix phase.

The packing of spherical particles has been studied thoroughly and the best packing of monomodal spheres results in 74% efficient space filling, with a random packing resulting in a density of about 63%, or the practical limit for monomodal packing. Pauling's rules for packing of spheres shows that perfect packing results in two different sized interstitial voids throughout the structure. To fill the larger voids with smaller spheres, one would target a radius ratio of small particle to big particle of 0.414. To fill the smaller voids would require a radius ratio of small particle to big particle of 0.225. Using a trimodal distribution of spherical particles in accordance with the present invention and assuming perfect packing of the system, 81% of the space. Naturally, this process could be continued filling the voids between the spheres with smaller and smaller spheres, but there is a diminishing return and physical limits that prohibit packing to 100% density by this approach. With particles in the micron range and traditional processing techniques, a density of 70% would be achievable and anything higher would be a significant advance in the art.

Depending on the circumstances, it may be desirable to maximize the dielectric constant of the planarizing agent and/or the planarizing composition formed therefrom. Most polymers have dielectric constants ranging from 2 to 10. Most glasses are not much higher, but glasses with high lead or bismuth contents can have dielectric constants upwards of 40. The best way to achieve the high dielectric constant is to use a metal oxide such as barium titanate. To achieve this at low processing temperatures may require a dielectric precursor approach. Metal oxide precursors can form traditional high dielectric constant morphologies at low temperatures. The compositions and methods of the present invention can produce a high ceramic yield and a high degree of crystallinity.

The present invention is also particularly useful for making low loss materials. Some of the major classes of materials that can be utilized or formed by the present invention include: Ba-Ln-Ti—O (Ln=Nd, Sm), (Zn,Sn),(Ti,Sn)_{y}O₄, Ba₂Ti₉O₂₀Ba₃Ta₂MeO₉ (Me=Zn or Mg). Specific examples include: Ba—Pb—Nd—Ti—O, Ba(Mg_{1/3}Ta_{2/3})O₃—BaO—Nd₂O₃-5TiO₂ Ba_{4.5}Nd₉Ti₁₈O₅₄, with small additions of Bi₂O or bismuth titanate, ReBa₃Ti₂O_{8.5} (Re═Y, Nd, and Sm), Ba_{3.75}Nd₉₅Ti₁₈O₅₄ with 1.0-4.0 wt. % Bi₂O₃BaO-Ln₂O₃-5TiO₂ (Ln=La, Pr, Nd, Sm), BaO—Nd₂O₃TiO₂Ba₆₋ₛ(Sm_{1-y}Nd_{y})₈+2×/3Ti₁₈O₅₄, (Ba,Pb)O—Nd₂O₃—TiO₂ (CaO doped) and Ti_{0.94}Zr_{0.4}Sn_{0.66}O₄.

Another class of materials that can be utilized are the pyrochlores, having the general formula A₂B₂O₇, for example Pb₂Ta₂O₇. The present invention is useful for making high dielectric constant materials. One family of materials that can be used are those having a perovskite structure. Examples include metal titanates, metal zirconates, metal niobates, and other mixed metal oxides. Of extensive use has been the barium titanate system, which can reach a broad range of dielectric performance characteristics by adding small levels of dopant ions. Specific examples include: BaTiO₃, PbTiO₃, PbZrO₃, PbZrₓTi₁₋ₓO, PbMg_{1/3}Nb_{2/3}O₃.

3. Polymers

The planarizing agent in accordance with the present invention can also include one or more polymers or monomers for forming one or more polymers. The polymers can be thermoplastic polymers or thermoset polymers. Thermoplastic polymers are characterized by being fully polymerized. They do not take part in any reactions to further polymerize or cross-link to form a final product. Typically, such thermoplastic polymers are melt-cast, injection molded or dissolved in a solvent. Examples include polyimide films, ABS plastics, vinyl, acrylic, polyurethane, styrene polymers of medium or high molecular weight and the like.

The polymers can also be thermoset polymers, which are characterized by not being fully polymerized or cured. The components that make up thermoset polymers must undergo further reactions to form fully polymerized, cross-linked or dense final products. Thermoset polymers tend to be resistant to solvents, heat, moisture and light.

A typical thermoset polymer mixture initially includes a monomer, resin or low molecular weight polymer. These components require heat, hardeners, light or a combination of the three to fully polymerize. Hardeners are used to speed the polymerization reactions. Some thermoset polymer systems are two part epoxies that are mixed at consumption or are mixed, stored and used as needed.

Specific examples of thermoset polymers include amine or amide-based epoxies such as diethylenetriamine, polyglycoldianine and triethylenetetramine. Other examples include imidazole, aromatic epoxies, brominated epoxies, thermoset PET, phenolic resins such as bisphenol-A, polymide, acrylics, urethanes, and silicones. Hardeners can include isophoronediamine and meta-phenylenediamene.

The polymer can also be an ultraviolet or other light-curable polymer. The polymers in this category are typically UV and light-curable materials that require photoinitiators to initiate the cure. Light energy is absorbed by the photoinitiators in the formulation causing them to fragment into reactive species, which can polymerize or cross-link with other components in the formulation. In acrylate-based adhesives, the reactive species formed in the initiation step are known as free radicals. Another type of photoinitiator, a cationic salt, is used to polymerize epoxy functional resins generating an acid, which reacts to create the cure. Examples of these polymers include cyanoacrylates such as z-cyanoacrylic acid methyl ester with an initiator as well as typical epoxy resin with a cationic salt. 4. Additives

Additives that may be included in the planarizing agent include reducing agents, crystallization inhibitors, adhesion promoters, rheology modifiers.

In one aspect of the invention, the planarizing agent comprises a reducing agent, for example, to facilitate the conversion of a dielectric precursor to a dielectric material at a desired temperature. Examples of reducing agents include amino alcohols and formic acid. Alternatively, the precursor conversion process can take place under reducing atmosphere, such as nitrogen, hydrogen or forming gas.

In some cases, the addition of reducing agents results in the formation of the dielectric material even under ambient conditions. Optionally, the reducing agent is part of the precursor itself, for example in the case of certain ligands.

The planarizing agent may also include a crystallization inhibitor in order to form an amorphous substantially non-conductive film. A preferred crystallization inhibitor is lactic acid. Such inhibitors reduce the formation of large crystallites directly from the dielectric precursor, which can be detrimental. Other crystallization inhibitors include ethylcellulose and polymers such as styrene allyl alcohol (SAA) and polyvinyl pyrollidone (PVP). In other cases, small amounts of glycerol can act as a crystallization inhibitor. Other compounds useful for reducing crystallization are other polyalcohols such as malto dextrin, sodium carboxymethylcellulose and TRITON X100. In general, solvents with a higher melting point and lower vapor pressure inhibit crystallization of any given compound more than a lower melting point solvent with a higher vapor pressure. In one embodiment, not greater than about 10 weight percent crystallization inhibitor as a percentage of total composition is added, preferably not greater than 5 weight percent and more preferably not greater than 2 weight percent.

The planarizing agent can also include an adhesion promoter adapted to improve the adhesion of the ultimately formed planarizing feature to the underlying substrate. For example, polyamic acid can improve the adhesion of the composition to a polymer substrate.

The planarizing agent described herein optionally includes one or more rheology modifiers, for example, to reduce spreading on the substrate. Rheology modifiers include SOLTHIX 250 (Avecia Limited), SOLSPERSE 21000 (Avecia Limited), styrene allyl alcohol (SAA), ethyl cellulose, carboxy methylcellulose, nitrocellulose, polyalkylene carbonates, ethyl nitrocellulose, and the like. These additives can reduce the spreading after deposition. Surfactants and wetting agents may also be used, as they can also help control spreading.

The planarizing agent can also include other additives such as wetting angle modifiers, humectants and the like.

IV. Processes for Planarizing Substrates

As indicated above, one problem associated with the formation of printable electronic features is substrate variability. Although many substrates provide substantially planar surfaces on a macroscopic scale, such surfaces often possess surface irregularities on a microscopic scale. As used herein, the term “surface irregularities” means features or characteristics, which impart a non-planar form to a substrate. Surface irregularities may be an inherent property of the substrate material itself, or they may be formed by the intentional formation of a feature on a substrate.

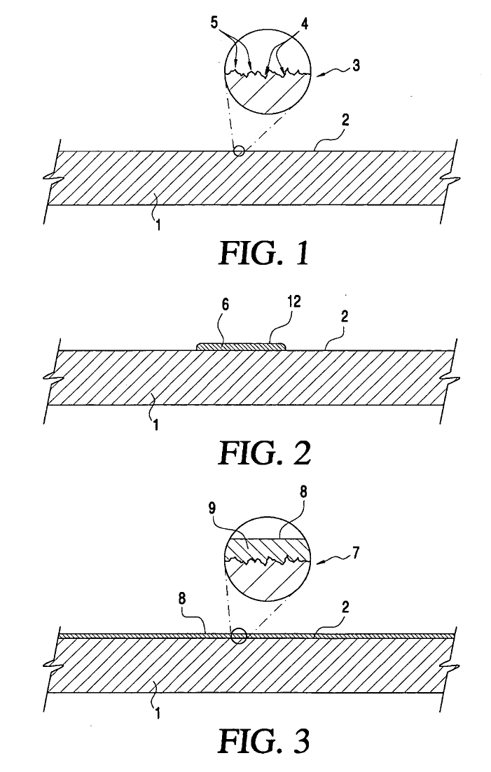

FIG. 1, for example, illustrates surface irregularities that are inherent to a particular substrate material. As shown, FIG. 1 illustrates a substrate, generally designated 1, having a substantially planar surface 2. Although the substantially planar surface 2 appears very planar on a macroscopic scale, the surface actually includes many surface irregularities, as shown by magnified inset 3. Specifically, the surface irregularities shown in FIG. 1 include peaks 5 and valleys 4 arranged in a highly disordered, random manner.

The presence of such surface irregularities may be problematic for providing printable electronic features having predictable electronic properties. Specifically, as one or more electronic inks are applied to a substrate such as substrate I shown in FIG. 1, a portion of the electronic ink will fill the valleys 4, resulting in waste. Additionally, peaks 5 may undesirably extend into the ultimately formed electronic feature thereby undesirably and unpredictably modifying the electrical characteristics thereof.

FIG. 2 illustrates an intentionally formed surface irregularity. Specifically, the surface irregularity shown in FIG. 2 is an electronic feature 6 disposed on the surface 2 of base substrate 1. The electronic feature 6 has an electronic feature surface 12, which is shown extending in a laterally extending plane parallel to surface 2 of base substrate 1. The electronic feature 6 may be a conventional non-printed electronic feature or, alternatively, a printed electronic feature. In either case, it may be desired to form a second electronic feature, e.g., a printed electronic feature, in a separate laterally extending plane, distally oriented with respect to the first electronic feature 6. That is, it may be desired to form a multi-layer electronic feature or features. In order to form such a multi-layer electronic feature, it may be desired to planarize an underlying substrate in order to render it suitable for receiving a subsequent layer. Collectively, the electronic feature 6 and the base substrate 1 form the “first substrate,” which may be planarized according to the present invention. In other words, the first substrate comprises the base substrate 1 and a preformed electronic feature 6 disposed thereon, the preformed electronic feature forming at least a portion of the surface irregularity.

According to one aspect of the present invention, a substrate having a surface with a surface irregularity may be planarized with a “planarizing agent,” defined herein as an ink suitable for forming a planarizing feature having a substantially planar surface. Specifically, the process comprises the steps of: (a) providing a first substrate having a first surface, wherein the first surface has a surface irregularity; (b) applying a planarizing agent to at least a portion of the first surface; (c) treating the applied planarizing agent under conditions effective to form the second substrate, the second substrate comprising the first substrate and a planarizing feature formed from the planarizing agent, wherein the second substrate has a planar surface formed at least in part of the planarizing feature, the planar surface being more planar than the first surface; and (d) forming an electronic feature on the planar surface.

A. Applicatiion of the Planarizing Agent

The step of applying the planarizing agent to at least a portion of the first surface may be performed in a variety of manners. In various embodiments, the planarizing agent is applied to the first substrate by a printing process. The printing process may be selected from intaglio printing, gravure printing, lithographic printing and flexographic printing processes. Other deposition techniques that may be used include roll printer, spraying, dip coating, spin coating, and other techniques that direct discrete units of fluid or continuous jets, or continuous sheets of fluid to a surface. In a preferred aspect, the planarizing agent is applied to the first substrate by a direct write printing process, such as by ink-jet printing.

The placement and thickness of the planarizing agent on the first substrate will depend on several factors such as the relative size and type of surface irregularity, and the relative material in the planarizing agent that will ultimately form the planarizing feature. If the surface irregularity comprises an inherent substrate surface irregularity, as shown in FIG. 1, then the planarizing agent preferably is applied on the first substrate in one or more layers and in an amount sufficient to fill at least a portion of the valleys formed by the surface irregularity. It may be necessary to apply multiple layers of planarizing agent, e.g., in multiple passes of an ink-jet printing head, in order to provide sufficient planarizing agent to ultimately form a planarizing feature that fills the valleys of the surface irregularity. In another aspect, the planarizing agent is applied in a manner sufficient to form a planarizing feature that covers the peaks in addition to the valleys of the surface irregularity. This aspect of the invention is illustrated in FIG. 3. Of course, in other aspects, the planarizing agent is applied in an amount to form a planarizing feature that covers some, but not all of the peaks.

The thickness of the applied planarizing agent may be controlled in a variety of manners. For example, the thickness may be controlled by: (1) controlling the relative amount of components in the planarizing agent that will form the planarizing feature after treating; (2) controlling the ink density by controlling the number of passes of a printing head; and/or (3) modulating drop volume.

Additionally, it is noted that the application of the planarizing agent may be an open loop system or a closed loop system. In an open system, the timing and characteristics of a printing sequence are predetermined and are not varied based on any parameters that are determined during the printing process. In a closed loop system, substrate information, e.g., degree of planarization, is determined and sent to a control unit, which determines whether the printing parameters need to be modified and/or repeated in order to provide improved planarization.

FIG. 3 illustrates a substrate 1 having a surface 2 with many surface irregularities in the form of microscopic peaks and valleys. The substrate 1 has been planarized with a planarizing agent to form a planarizing feature 9. The planarizing feature 9 preferably comprises a dielectric (substantially non-conductive) material so as to not interfere with one or more electronic features, not shown, which features are subsequently applied to the planarized substrate. The planarizing feature 9 preferably has a highly planar surface 8, which is more planar than the substantially planar surface 2 of the substrate 1.

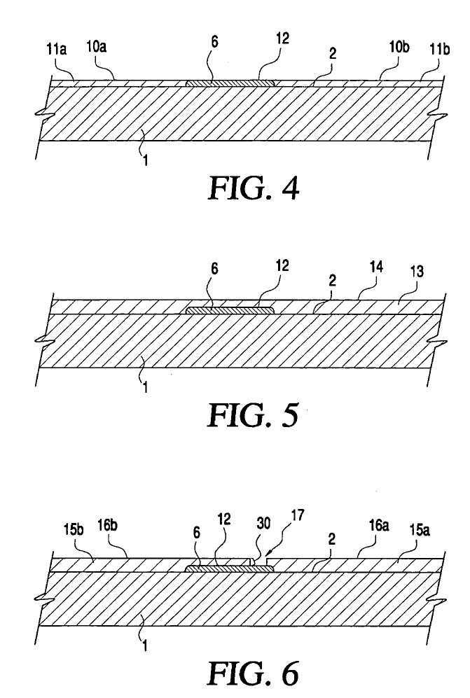

If the surface irregularity comprises an electronic feature, as shown in FIG. 2, then the planarizing agent preferably is applied to the substrate surface adjacent to (laterally with respect to) the preformed electronic feature in the applying step. Additionally, the thickness of the planarizing agent preferably is sufficient to form a planarizing feature adjacent to the surface irregularity formed by the electronic feature. Depending on the degree to which the electronic feature extends distally with respect to the substrate surface, it may be necessary to apply the planarizing agent to the substrate in a plurality of passes. In a preferred embodiment, the planarizing agent is applied in an amount sufficient to ultimately form a planarizing feature having a planar surface that is aligned with the surface of the electronic feature, if any. That is, the planar surface of the planarizing feature preferably is in the same laterally extending plane as the surface of the electronic feature, if any. Thus, the planar surface of the planarizing feature in combination with the surface of the electronic feature forms a composite surface on which a subsequent layer optionally may be applied. This aspect of the invention is shown in FIG. 4.

As shown, FIG. 4 illustrates an electronic feature 6 disposed on surface 2 of base substrate 1. The electronic feature 6 has an electronic feature surface 12, shown extending in a laterally extending plane that is parallel with surface 2 of base substrate 1. In this aspect, the electronic feature 6 in combination with the base substrate 1 constitutes a “first substrate” having a surface irregularity formed by the electronic feature 6. As shown, the first substrate has been planarized with a planarizing agent to form planarizing features 11a and 11b disposed on the surface 2 of base substrate 1. The planarizing features 11a and 11b form highly planar surfaces 10a and 10b, respectively. As shown, the highly planar surfaces 10a and 10b form laterally extending planar surfaces that are aligned (laterally) with respect to electronic feature surface 12. That is, the highly planar surfaces 10a and 10b lie substantially in the same geometric plane as the electronic feature surface 12 of the electronic feature 6. Thus, in this embodiment of the present invention, a composite planar surface is formed, which comprises the highly planar surfaces 10a and 10b of planarizing features 11a and 11b in combination with electronic feature surface 12 of preformed electronic feature 6. Optionally, one or more secondary electronic features, not shown, may be formed, e.g., by an ink-jet printing process, on top of (or distally with respect to) this composite planarized surface.

It is important that the planarizing agent be applied in an amount sufficient to form a planarizing feature having a planar surface that is more planar that the first surface of the first substrate (prior to application of the planarizing agent). Additionally, as one skilled in the art would appreciate, the thickness of the applied planarizing agent typically will not reflect the thickness of the ultimately formed planarizing feature (post treatment). According, it is important to take into account the relative percentage of components contained in the planarizing agent that will ultimately form the planarizing agent after treatment of the applied planarizing agent. For example, if the planarizing agent comprises a liquid vehicle that is removed (vaporized) during the treating step to form a planarizing feature, the volume of planarizing agent that should be applied will be greater than the volume of the planarizing feature ultimately formed. Accordingly, it is necessary to calculate the amount of planarizing agent that is necessary to be applied to a substrate surface in order to form a planarizing feature having a desired thickness. Such calculations are well within the purview of one skilled in the art.

B. Treating the Applied Planarizing Agent

The treating of the applied planarizing agent to form the planarizing feature of the present invention may be achieved by a variety of processes. For example, the treating step may comprise one or more of the following steps: (1) heating the applied planarizing agent; (2) subjecting the applied planarizing agent to electromagnetic radiation (e.g., UV radiation); and/or (3) applying a hardening agent to the applied planarizing agent. Thus, the treating step may comprise subjecting the applied planarizing agent to some form of radiation (e.g., thermal or electromagnetic) and/or applying an additional composition, which interacts or reacts with the planarizing agent to form the planarizing feature.

In one aspect, the planarizing agent comprises a liquid vehicle, and the treating step comprises drying, e.g., through heating optionally in a vacuum or partial vacuum, the applied planarizing agent under conditions effective to remove a weight majority (preferably at least 80 wt. %, at least 90 wt. %, at least 95 wt. %, or at least 99 wt. %) of the liquid vehicle from the applied planarizing agent. As the liquid vehicle is removed, particulates contained in the planarizing agent, if any, will coalesce, optionally adhere to one another (agglomerate), and form the planarizing feature of the present invention. Additionally or alternatively, the planarizing agent comprises dissolved dielectric precursors, which precipitate out of solution as the liquid vehicle (solvent) is removed.

Desirably, the liquid vehicle can be removed to form a planarizing feature by heating the applied planarizing agent to a low maximum temperature. The preferred conversion temperature (maximum heating temperature) is less than about 900° C. for ceramic substrates. For glass substrates, the preferred conversion temperature is not greater than about 600° C. Even more preferred for glass substrates is a conversion temperature of not greater than about 500° C., such as not greater than about 400° C. The preferred conversion temperature for organic substrates is not greater than about 350° C., even more preferably not greater than about 300° C., and even more preferably not greater than about 200° C. In other embodiments, the liquid vehicle may be removed by heating to a maximum temperature of about 150° C., about 100° C., about 50° C. or at ambient temperature. In this aspect, the planarizing agent optionally further comprises a polymer selected from the group consisting of an acrylic polymer, a polystyrene and a polyurethane. A planarizing agent comprising such a polymer (e.g., thermoplastic) may be an emulsion or solution.

The length of time that the applied planarizing agent is optionally heated depends on the volatility of the liquid vehicle and the relative amount of liquid vehicle contained in the planarizing agent. In various embodiments, the heating occurs for less than 10 minutes, less than 5 minutes, less than 1 minute or a few seconds.

As indicated above, the planarizing agent optionally comprises an ultraviolet, light, or other electromagnetic radiation-curable polymer. Thus, in one aspect, the planarizing agent comprises a UV or light curable composition, and the treating step comprises applying UV radiation to the applied planarizing agent. The polymers in this category are typically UV and light-curable materials that require photoinitiators to initiate the cure. Light energy is absorbed by the photoinitiators in the formulation causing them to fragment into reactive species, which can polymerize or cross-link with other components in the formulation. In acrylate-based adhesives, the reactive species formed in the initiation step are known as free radicals. Another type of photoinitiator, a cationic salt, may be used to polymerize epoxy functional resins generating an acid, which reacts to create the cure. Examples of these polymers include cyanoacrylates such as z-cyanoacrylic acid methyl ester with an initiator as well as typical epoxy resin with a cationic salt.

In another aspect, the planarizing agent comprises a polymer resin and the treating step comprises applying a hardener to the planarizing agent under conditions effective to form the planarizing composition. In this aspect, the polymer resin may be a thermoset polymer, which is characterized by not being fully polymerized or cured. The components that make up thermoset polymers undergo further reactions upon contacting the hardener (optionally in combination with heating or UV or light curing) to form fully polymerized, cross-linked or dense final products. Ideally, the planarizing agent and the hardener are two-part epoxies that are mixed at consumption or are mixed, stored and used as needed. Specific examples of thermoset polymers and hardeners are discussed in more detail above.

C. Composition of the Planarizing Feature

The composition of the planarizing feature depends directly on the composition of the planarizing agent and on the treating conditions implemented. As indicated above, the planarizing feature preferably comprises a dielectric composition and is substantially non-conductive so that it does not electrically interfere with electronic features previously formed or subsequently formed thereon.

In one aspect, the planarizing feature comprises a dielectric composition in an amount greater than about 50 wt. %, greater than about 80 wt. %, greater than about 95 wt. % or greater than about 99 wt. %. In one aspect, the planarizing feature comprises a substantially non-conductive material selected from the group consisting of a dielectric material, glass, silica, titania, alumina and a silane.

As indicated above, the planarizing agent optionally comprises dielectric particles (micro or nano). During formation of the planarizing feature from the planarizing agent the dielectric particles preferably fuse to adjacent dielectric particles to form a network of interconnected dielectric nodes. The degree to which the particles are interconnected to one another depends largely on the treating conditions implemented. Under mild treating conditions (e.g., low temperatures), a porous network of necked dielectric nodes may be formed. Porosity can be monitored and measured by Nitrogen BET (Brunauer, Emmett and Teller), Mercury porosimetry, or DBP methods. Under limited circumstances, porosity may be desired as air acts as a generally good insulator. Under harsher treating conditions (e.g., higher temperatures), a substantially nonporous planarizing feature may be formed.

The thickness of the planarizing feature also will vary widely, depending mostly on the size and degree of the surface irregularity on the first substrate. In a preferred embodiment, the thickness of the planarizing feature will be as low as possible in order to minimize waste, while providing maximum planarity. For microscopic surface irregularities that are inherent to the substrate material (see FIG. 1), the thickness of the ultimately formed planarizing feature may range from about 0.2 to about 20 μm, e.g., from about 0.5 to about 10 μm or from about 1 to about 5 μm. For larger surface irregularities, such as the electronic feature 6 shown in FIG. 2, the thickness of the ultimately formed planarizing feature may be greater ranging, for example, from about 5 to about 30 μm, e.g., from about 10 to about 20.

Of course, in order to be planarizing, the planarizing feature should have a highly planar surface that is more planar than the first substrate on which it is formed. Surface roughness may be measured by the RMS (root mean square) value, which is a statistical description that may be determined by a profilometer.

After formation of the planarizing feature, it may be desired to form an electronic feature thereon. Thus, in one embodiment, the process further comprises the steps of: applying a first ink onto at least a portion of the planarizing feature, and treating the first ink under conditions effective to form at least a portion of the electronic feature. Various possible compositions and treating conditions for formation of electronic features from the first ink are discussed above.

V. Processes for Encapsulating Electronic Features

As indicated above, in another aspect, the invention is to a process for forming an encapsulated electronic feature. In this embodiment, the invention comprises the steps of (a) direct write printing a first ink onto a substrate; (b) treating the first ink under conditions effective to form at least a portion of a first electronic feature; (c) applying an encapsulating agent to the at least a portion of the first electronic feature; and (d) treating the applied encapsulating agent under conditions effective to form an encapsulated electronic feature comprising an encapsulation layer and the at least a portion of the first electronic feature.

This embodiment of the present invention is substantially similar to the above-described planarization aspect of the present invention. The primary difference is that by encapsulating an electronic feature, at least a portion of the electronic feature is covered (longitudinally) by an encapsulating layer, while planarizing entails forming planarization features in the absence of an electronic feature (see FIG. 3) and/or adjacent (laterally) to an electronic feature (see FIG. 4) in order to form a highly planar surface on which another electronic feature may be formed.

The purpose for encapsulating an electronic feature also is different than the purpose for forming a planarizing feature. The primary purpose for encapsulating an electronic feature is to protect the feature (or portion thereof) from atmospheric degradation. As indicated above, oxygen and water vapor may degrade an electronic feature. By encapsulating the electronic feature with an encapsulation layer, however, a barrier is formed, which inhibits contacting of atmospheric air and/or water with the underlying electronic feature. Of course, some degree of planarization may be achieved by encapsulating an electronic feature.

FIG. 5 illustrates an encapsulated electronic feature 6 disposed on surface 2 of base substrate 1. The electronic feature 6 has an electronic feature surface 12, shown extending in a laterally extending plane that is parallel with surface 2 of base substrate 1. As shown, the electronic feature 6 is fully encapsulated by an encapsulation layer 13. The encapsulation layer 13 optionally has a highly planar surface 14. Since the electronic feature 6 is fully encapsulated, atmospheric degradation of the electronic feature 6 desirably is inhibited. Optionally, one or more secondary electronic features, not shown, may be formed, e.g., by an ink-jet printing process, on top of (or distally with respect to) the highly planar surface 14.

Additionally, encapsulation layers having conductive vias may be formed according to the present invention. Such encapsulation layers are highly desirable in that they can protect a proximally oriented first electronic feature from atmospheric degradation while simultaneously providing a means for allowing the first electronic feature to conductively communicate with a distally oriented second electronic feature. The encapsulation layer also desirably insulates longitudinally situated electronic components (e.g., situated in longitudinally parallel planes from one another) from one another in regions where conductive communication is not desired. FIGS. 6-8 illustrate the formation of an encapsulating layer that includes a via connecting longitudinally adjacent electronic features to one another.

FIG. 6 illustrates a partially encapsulated electronic feature 6 disposed on surface 2 of base substrate 1. The electronic feature 6 has an electronic feature surface 12, shown extending in a laterally extending plane that is parallel with surface 2 of base substrate 1. As shown, the electronic feature 6 is partially encapsulated by encapsulation layers 15a and 15b having planar surfaces 16a and 16b. Encapsulation layers 15a and 15b are separated from one another by a void 17. Void 17 may be formed, for example, by modifying the timing of the deposition of an ink-jet printing head. Thus, in one aspect, the encapsulation agent is selectively applied to at least a portion of a first electronic feature in the applying step to form a void in the encapsulation layer. Alternatively, void 17 may be formed by etching, lasing or chemically treating a fully encapsulating layer, as shown, for example in FIG. 5.

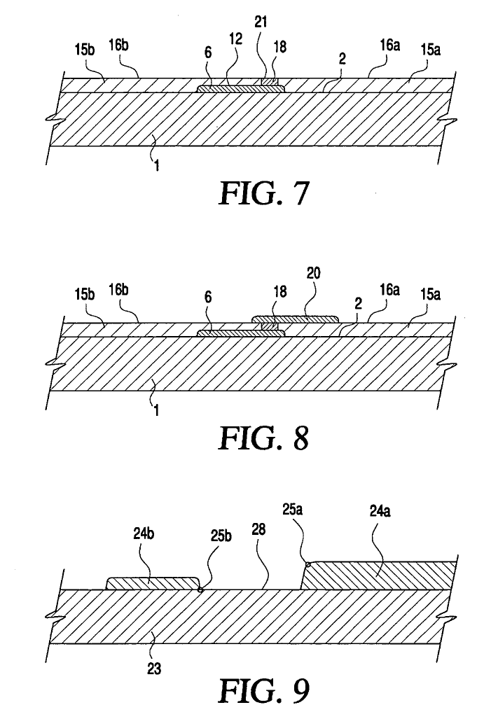

Preferably, an electronic ink (in this aspect, referred to as a “via ink”) is deposited in the void, e.g., through a printing process, preferably a direct write printing process such as ink-jet printing. In order to minimize bleeding between the encapsulating agent and the electronic ink, it is preferred that the encapsulating agent be treated to form the encapsulating layers 15a and 15b prior to deposition of the electronic ink into void 17. The deposited electronic ink may then be treated, as discussed above, to form an electronic feature, e.g., via 18, in void 17, as shown in FIG. 7. Thus, in one aspect, the encapsulation process further comprises the steps of applying a via ink to at least a portion of the void 17, and treating the applied via ink under conditions effective to form avia 18.

The dimensions of void 17 may vary widely depending on the desired size of the via that is ultimately to be formed within the void. In various embodiments, the narrowest lateral distance between the encapsulation layers 15a and 15b (e.g., the longitudinal distance formed by the void) ranges from about 10 μm to about 300 μm, e.g., from about 20 μm to about 200 μm or from about 50 μm to about 100 μm. Similarly, the thickness 30 of the portion of the encapsulation layer that longitudinally covers a portion of electronic feature 6 may vary widely. In various embodiments, the thickness ranges from about 2 μm to about 50 μm, e.g., from about 5 μm to about 25 μm or from about 10 μm to about 20 μm.

Reverting to FIG. 7, via 18 is shown having surface 21, which is longitudinally aligned in substantially the same plane as planar surfaces 16a and 16b. By forming via 18 having surface 21 in substantially the same plane as planar surfaces 16a and 16b of encapsulation layers 15a and 15b, a composite surface is formed on which a second electronic feature 20 may be formed, as shown in FIG. 8.

Thus, in a preferred aspect, the process further comprises the step of applying a second ink on at least a portion of the encapsulation layer(s) 15a and/or 15b. Additionally, the process optionally further comprises the step of treating the second ink under conditions effective to form at least a portion of a second electronic feature 20, as shown in FIG. 8. As shown, the second electronic feature 20 is electrically coupled to the first electronic feature 6 by the via 18. Optionally, the steps of treating the via ink and of treating the second ink occur simultaneously, e.g., in a single treating step. Alternatively, the steps occur sequentially.

In another embodiment, the electronic feature 6 and the electronic feature 20 are portions of a first electronic feature (e.g., of an active electronic feature). In this aspect, the process optionally further comprises the steps of treating the second ink under conditions effective to form a second portion (e.g., the electronic feature 20) of the first electronic feature, and the second portion is electrically coupled by the via to a first portion (e.g., the electronic feature 6) of the first electronic feature, the first portion being formed in the step of treating the first ink. As indicated above, the steps of treating the via ink and of treating the second ink optionally occur simultaneously, e.g., in a single treating step. Alternatively, the steps occur sequentially.

As indicated above, the composition of the encapsulating agent is as disclosed above with reference to the planarization agent, and this section of the specification incorporates that section in its entirety as if it referred to the composition of the encapsulating agent.

Similarly, the step of treating the encapsulating agent to form the encapsulation layer may be performed by any of the above-described process steps for converting the planarizing agent to the planarizing feature, and that section is also incorporated herein in its entirety as if it referred to the formation of an encapsulating layer from an encapsulating agent. For example, in one embodiment, the encapsulating agent comprises a UV curable composition and the step of treating of the applied encapsulating agent comprises applying UV radiation to the applied encapsulating agent. In another embodiment, the encapsulating agent comprises a polymer resin and the step of treating the applied encapsulating agent comprises applying a hardener to the encapsulating agent under conditions effective to form the encapsulation layer. In yet another aspect, the encapsulating agent comprises a liquid medium and the step of treating the applied encapsulating agent comprises heating the applied encapsulating agent (e.g., to a maximum temperature of less than about 200° C.) under conditions effective to remove a weight majority of the liquid vehicle from the applied encapsulating agent and form the encapsulation layer.

VI. Processes for Forming Ramp Features

As indicated above, in another aspect, the invention is to a process for forming a ramp feature, the process comprising the steps of: (a) providing a substrate having a substantially planar surface and a three-dimensional electronic feature disposed on the substantially planar surface, the three-dimensional electronic feature having a connection point disposed longitudinally relative to the substantially planar surface; (b) applying a ramping agent to the substantially planar surface adjacent the electronic feature; and (c) treating the applied ramping agent under conditions effective to form the ramp feature extending angularly, relative to the substantially planar surface, from a first point on the substantially planar surface to the connection point.

The ramping embodiment of the present invention is similar to the above-described planarization aspect of the present invention in many respects. The primary difference is that a ramp feature typically will typically form a surface (which preferably is substantially planar) that is obliquely oriented with respect to the base substrate surface, rather than being oriented in a plane parallel to the surface of the base substrate. That is, by definition, a ramp feature forms a planar surface that is not parallel to the base substrate surface.

The purpose of forming a ramp feature according to the present invention is to provide a surface on which an electronic feature can be formed, for example, to electronically connect a first electronic feature (or a first connection point thereon) with a second electronic feature (or a second connection point thereon), wherein the first and second electronic features (and/or first and second connection points thereon) are longitudinally and laterally spaced from one another.

FIG. 9, for example, illustrates two electronic features 24a and 24b disposed on base substrate 23. Each electronic feature 24a and 24b has a connection point 25a and 25b, respectively. As shown, connection points 25a and 25b are longitudinally and laterally spaced with respect to one another. In other words, each of connection points 25a and 25b is positioned a different distance from surface 28 of base substrate 23. Accordingly, it may be difficult if not impossible to electronically connect electronic features 24a and 24b to one another.

As indicated above, the present invention provides the ability to form a ramp feature between two connection points 25a and 25b. An electronic feature may subsequently be formed on the ramp feature in order to connect the connection points 25a and 25b.

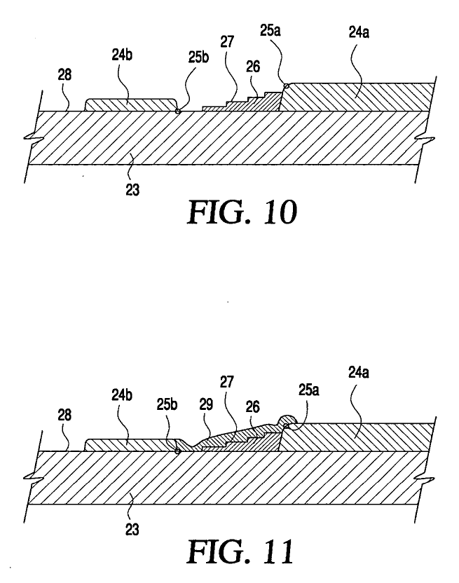

In a preferred embodiment, a ramping agent is applied to surface 28 of base substrate 23. The applied ramping agent is then treated, e.g., by any of the above-described treating processes, to form a ramp feature 27, as shown in FIG. 10. The ramp feature 26 preferably has a ramp surface 27, which extends angularly, relative to the substantially planar surface 28, from a first point on the substantially planar surface 28 to the distal connection point 25a (or to a region immediately longitudinally and laterally adjacent to the distal connection point 25a). In this context, the angularly-extending ramp optionally comprises a smooth surface (not shown) and/or a series of steps (as shown) extending from the first point on the substantially planar surface 28 to the distal connection point 25a.

In a preferred embodiment, as shown in FIG. 11, an electronic ink is applied onto at least a portion of the ramp feature, and the applied electronic ink is treated under conditions effective to form at least a portion of a ramped electronic feature 29 on ramp surface 27 of ramp feature 26. In this manner, the ramped electronic feature 29 connects the connection point 25b with connection point 25a, as shown in FIG. 11. In a preferred embodiment, the ramped electronic feature 29 preferably contacts connection points 25a and/or 25b. Thus, ramped electronic feature 29, for example, preferably comprises a conductor that electrically couples the electronic feature 24a with electronic feature 24b.

The dimensions of ramp feature 26 may vary widely depending in large part on the longitudinal spacing between the connection points to be connected. In order to be deemed a “ramp feature,” however, it is important that the feature has an increasing longitudinal thickness to form a ramp surface that is angularly (obliquely) oriented with respect to the surface 28 of substrate 23. As the ramping agent preferably is applied by an direct write printing process, it is contemplated that, at least on a microscopic level, the ramp surface 28 may be formed of a series of step-like structures, as shown in FIG. 10.

As indicated above, the composition of the ramping agent is as disclosed above with reference to the planarization agent, and this section of the specification incorporates that section in its entirety as if it referred to the composition of the ramping agent rather than the planarization agent.

Similarly, the step of treating the ramping agent to form the ramp feature may be performed by any of the above-described process steps for converting the planarizing agent to the planarizing feature, and that section is also incorporated herein in its entirety as if it referred to the formation of an ramp feature from an ramping agent. For example, in one embodiment, the ramping agent comprises a UV curable composition and the step of treating of the applied ramping agent comprises applying UV radiation to the applied ramping agent. In another embodiment, the ramping agent comprises a polymer resin and the step of treating the applied ramping agent comprises applying a hardener to the ramping agent under conditions effective to form the ramp feature. In yet another aspect, the ramping agent comprises a liquid medium and the step of treating the applied ramping agent comprises heating the applied ramping agent (e.g., to a maximum temperature of less than about 200° C.) under conditions effective to remove a weight majority of the liquid vehicle from the applied ramping agent and form the ramp feature.

It is understood that the words that have been used are words of description and illustration, rather than words of limitation. Changes may be made, within the purview of the appended claims, as presently stated and as amended, without departing from the scope and spirit of the present invention in its aspects. Although the invention has been described herein with reference to particular means, materials and embodiments, the invention is not intended to be limited to the particulars disclosed herein. Instead, the invention extends to all functionally equivalent structures, methods and uses, such as are within the scope of the appended claims.

What is claimed is:

1. A process for forming an electronic feature on a second substrate, the process comprising the steps of:
(a) providing a first substrate having a first surface, wherein the first surface has a surface irregularity;
(b) applying a planarizing agent to at least a portion of the first surface;
(c) treating the applied planarizing agent under conditions effective to form the second substrate, the second substrate comprising the first substrate and a planarizing feature formed from the planarizing agent, wherein the second substrate has a planar surface formed at least in part of the planarizing feature, the planar surface being more planar than the first surface; and
(d) forming an electronic feature on the planar surface.

2. The process of claim 1, wherein the first substrate comprises a base substrate and a preformed electronic feature disposed thereon, and wherein the preformed electronic feature forms at least a portion of the surface irregularity.

3. The process of claim 2, wherein the planarizing agent is applied adjacent to the preformed electronic feature in step (b).

4. The process of claim 3, wherein the planar surface is formed of at least the planarizing feature and a surface of the preformed electronic feature.

5. The process of claim 1, wherein the surface irregularity comprises microscopic peaks and valleys.

6. The process of claim 5, wherein the planarizing agent fills at least a portion of the valleys in step (b).

7. The process of claim 1, wherein the planarizing agent comprises a UV curable composition, and wherein step (c) comprises applying UV radiation to the applied planarizing agent.

8. The process of claim 1, wherein the planarizing agent comprises a polymer resin, and wherein step (c) comprises applying a hardener to the planarizing agent under conditions effective to form the planarizing feature.

9. The process of claim 1, wherein the planarizing agent comprises a liquid vehicle, and wherein step (c) comprises heating the applied planarizing agent under conditions effective to remove a weight majority of the liquid vehicle from the applied planarizing agent.

10. The process of claim 9, wherein the applied planarizing agent is heated to a maximum temperature of not greater than about 200° C.

11. The process of claim 9, wherein the planarizing agent further comprises a polymer selected from the group consisting of an acrylic polymer, styrene and a polyurethane.

12. The process of claim 1, wherein the planarizing agent comprises a substantially non-conductive material selected from the group consisting of a dielectric material, a dielectric precursor, glass, silica, titania, alumina, and a silane.

13. The process of claim 1, wherein the planarizing agent has a viscosity of less than about 50 centipoise.

14. The process of claim 1, wherein the planarizing agent has a surface tension of from about 10 dynes/cm to about 50 dynes/cm.

15. The process of claim 1, wherein the planarizing agent is direct write printed onto the at least a portion of the first surface in step (b).

16. The process of claim 1, wherein the planarizing feature is hydrophobic.

17. The process of claim 1, wherein the planarizing agent comprises an adhesion agent.

18. The process of claim 1, wherein the process further comprises the steps of:
(e) applying a first ink onto at least a portion of the planarizing feature; and
(f) treating the first ink under conditions effective to form at least a portion of the electronic feature.

19. The process of claim 1, wherein the first substrate is selected from the group consisting of a fluorinated polymer, polyimide, epoxy resin, polycarbonate, polyester, polyethylene, polypropylene, polyvinyl chloride, ABS copolymer, wood, paper, metallic foil, glass, flexible fiberboard, non-woven polymeric fabric, and cloth.

20. The process of claim 1, wherein the electronic feature is selected from the group consisting of a conductor, a resistor, a capacitor, an inductor, a dielectric and a semiconductor.

21. A process for forming an encapsulated electronic feature, the process comprising the steps of:
(a) direct write printing a first ink onto a substrate;
(b) treating the first ink under conditions effective to form at least a portion of a first electronic feature;
(c) applying an encapsulating agent to the at least a portion of the first electronic feature; and
(d) treating the applied encapsulating agent under conditions effective to form an encapsulated electronic feature comprising an encapsulation layer and the at least a portion of the first electronic feature.

22. The process of claim 21, wherein the encapsulating agent comprises a UV curable composition, and wherein step (d) comprises applying UV radiation to the applied encapsulating agent.

23. The process of claim 21, wherein the encapsulating agent comprises a polymer resin, and wherein step (d) comprises applying a hardener to the encapsulating agent under conditions effective to form the encapsulation layer.

24. The process of claim 21, wherein the encapsulating agent comprises a liquid vehicle, and wherein step (d) comprises heating the applied encapsulating agent under conditions effective to remove a weight majority of the liquid vehicle from the applied encapsulating agent.

25. The process of claim 24, wherein the applied encapsulating agent is heated to a maximum temperature of not greater than about 200° C.

26. The process of claim 24, wherein the encapsulating agent further comprises a polymer selected from the group consisting of an acrylic polymer, styrene and a polyurethane.

27. The process of claim 21, wherein the first ink comprises a metallic composition.

28. The process of claim 27, wherein the metallic composition comprises a metal selected from the group consisting of silver, gold, copper, nickel, cobalt, palladium, platinum, indium, tin, zinc, titanium, chromium, tantalum, tungsten, iron, rhodium, iridium, ruthenium, osmium and lead.

29. The process of claim 27, wherein the metallic composition comprises an alloy comprising at least two metals, each of the two metals being selected from the group consisting of silver, gold, copper, nickel, cobalt, palladium, platinum, indium, tin, zinc, titanium, chromium, tantalum, tungsten, iron, rhodium, iridium, ruthenium, osmium and lead.

30. The process of claim 21, wherein the first ink comprises a metal precursor to a metal, the metal being selected from the group consisting of silver, gold, copper, nickel, cobalt, palladium, platinum, indium, tin, zinc, titanium, chromium, tantalum, tungsten, iron, rhodium, iridium, ruthenium, osmium and lead.

31. The process of claim 21, wherein the encapsulating agent comprises a substantially non-conductive material selected from the group consisting of a dielectric material, a dielectric precursor, glass, silica, titania, alumina, and a silane.

32. The process of claim 21, wherein the encapsulating agent has a viscosity of less than about 50 centipoise.

33. The process of claim 21, wherein the encapsulating agent has a surface tension of from about 10 dynes/cm to about 50 dynes/cm.

34. The process of claim 21, wherein the encapsulating agent is direct write printed onto the at least a portion of the first electronic feature in step (c).

35. The process of claim 21, wherein the encapsulation layer is hydrophobic.

36. The process of claim 21, wherein the first electronic feature comprises a metal and wherein the metal is oxidized at a slower rate in the encapsulated electronic feature relative to an unencapsulated first electronic feature.

37. The process of claim 21, wherein the encapsulating agent comprises an adhesion agent.

38. The process of claim 21, wherein the process further comprises the step of:
(e) applying a second ink to at least a portion of the encapsulation layer.

39. The process of claim 38, wherein the process further comprises the step of:
(f) treating the second ink under conditions effective to form at least a portion of a second electronic feature.

40. The process of claim 39, wherein first electronic feature comprises a first conductive trace and the second electronic feature comprises a second conductive trace, and wherein the first and second conductive traces are insulated from one another by the encapsulation layer.

41. The process of claim 38, wherein the process further comprises the step of:
(f) treating the second ink under conditions effective to form a second portion of the first electronic feature.

42. The process of claim 21, wherein the substrate is selected from the group consisting of a fluorinated polymer, polyimide, epoxy resin, polycarbonate, polyester, polyethylene, polypropylene, polyvinyl chloride, ABS copolymer, wood, paper, metallic foil, glass, flexible fiberboard, non-woven polymeric fabric, and cloth.

43. The process of claim 21, wherein the encapsulating agent is selectively applied to the at least a portion of the first electronic feature in step (c) to form a void in the encapsulation layer, the process further comprising the steps of:
(e) applying a via ink to at least a portion of the void; and
(f) treating the applied via ink under conditions effective to form a via.

44. The process of claim 43, wherein the process further comprises the step of:
(g) applying a second ink on at least a portion of the encapsulation layer.

45. The process of claim 44, wherein the process further comprises the step of:
(h) treating the second ink under conditions effective to form at least a portion of a second electronic feature, the second electronic feature being electrically coupled to the first electronic feature by the via.

46. The process of claim 45, wherein steps (f) and (h) occur simultaneously.

47. The process of claim 44, wherein the process further comprises the step of:
(h) treating the second ink under conditions effective to form a second portion of the first electronic feature, the second portion being electrically coupled by the via to a first portion of the first electronic feature, the first portion being formed by the first ink in step (b).

48. The process of claim 47, wherein steps (f) and (h) occur simultaneously.

49. The process of claim 21, wherein the electronic feature is selected from the group consisting of a conductor, a resistor, a capacitor, an inductor, a dielectric and a semiconductor.

50. A process for forming a ramp feature, the process comprising the steps of:
(a) providing a substrate having a substantially planar surface and a three-dimensional electronic feature disposed on the substantially planar surface, the three-dimensional electronic feature having a connection point disposed longitudinally relative to the substantially planar surface;
(b) applying a ramping agent to the substantially planar surface adjacent the electronic feature; and
(c) treating the applied ramping agent under conditions effective to form the ramp feature extending angularly, relative to the substantially planar surface, from a first point on the substantially planar surface to the connection point.

51. The process of claim 50, wherein the ramping agent comprises a UV curable composition, and wherein step (c) comprises applying UV radiation to the applied ramping agent.

52. The process of claim 50, wherein the ramping agent comprises a polymer resin, and wherein step (c) comprises applying a hardener to the ramping agent under conditions effective to form the ramp feature.

53. The process of claim 50, wherein the ramping agent comprises a liquid vehicle, and wherein step (c) comprises heating the applied ramping agent under conditions effective to remove a weight majority of the liquid vehicle from the applied ramping agent.

54. The process of claim 53, wherein the applied ramping agent is heated to a maximum temperature of not greater than about 200° C.

55. The process of claim 53, wherein the ramping agent further comprises a polymer selected from the group consisting of an acrylic polymer, styrene and a polyurethane.

56. The process of claim 50, wherein the process further comprises the steps of:
(d) applying an electronic ink onto at least a portion of the ramp feature; and
(e) treating the applied electronic ink under conditions effective to form at least a portion of a second electronic feature on the ramp feature.

57. The process of claim 56, wherein at least a portion of the second electronic feature contacts the connection point.

58. The process of claim 57, wherein the second electronic feature comprises a conductor that electrically couples the first electronic feature with a third electronic feature.

59. The process of claim 56, wherein the electronic ink comprises a metallic composition.

60. The process of claim 59, wherein the metallic composition comprises a metal selected from the group consisting of silver, gold, copper, nickel, cobalt, palladium, platinum, indium, tin, zinc, titanium, chromium, tantalum, tungsten, iron, rhodium, iridium, ruthenium, osmium and lead.

61. The process of claim 59, wherein the metallic composition comprises an alloy comprising at least two metals, each of the two metals being selected from the group consisting of silver, gold, copper, nickel, cobalt, palladium, platinum, indium, tin, zinc, titanium, chromium, tantalum, tungsten, iron, rhodium, iridium, ruthenium, osmium and lead.

62. The process of claim 56, wherein the electronic ink comprises a metal precursor to a metal, the metal being selected from the group consisting of silver, gold, copper, nickel, cobalt, palladium, platinum, indium, tin, zinc, titanium, chromium, tantalum, tungsten, iron, rhodium, iridium, ruthenium, osmium and lead.

63. The process of claim 50, wherein the ramping agent comprises a substantially non-conductive material selected from the group consisting of a dielectric material, a dielectric precursor, glass, silica, titania, alumina, and a silane.

64. The process of claim 50, wherein the ramping agent has a viscosity of less than about 50 centipoise.

65. The process of claim 50, wherein the ramping agent has a surface tension of from about 10 dynes/cm to about 50 dynes/cm.

66. The process of claim 50, wherein the ramping agent is direct write printed onto at least a portion of the substantially planar surface in step (b).

67. The process of claim 50, wherein the ramp feature is hydrophobic.

68. The process of claim 50, wherein the ramping agent comprises an adhesion agent.

69. The process of claim 50, wherein the substrate is selected from the group consisting of a fluorinated polymer, polyimide, epoxy resin, polycarbonate, polyester, polyethylene, polypropylene, polyvinyl chloride, ABS copolymer, wood, paper, metallic foil, glass, flexible fiberboard, non-woven polymeric fabric, and cloth.

70. The process of claim 50, wherein the electronic feature is selected from the group consisting of a conductor, a resistor, a capacitor, an inductor, a dielectric and a semiconductor.
